(19) United States
(12) Patent Application Publication
(10) Pub. No.: US 2026/0293758 A1
(43) Pub. Date: Sep. 24, 2026

(54) PACKAGE STRUCTURE INCLUDING AN EMBEDDED ACTIVE DIE AND METHODS FOR FORMING THE SAME

(71) Applicant: Taiwan Semiconductor Manufacturing Company Limited, Hsinchu (TW)

(72) Inventors: Yi-Hsuan WU, Hsinchu (TW); Lipu Kris CHUANG, Hsinchu (TW); Yen-Ming CHEN, Hsinchu (TW); King-Ho TAM, Hsinchu (TW); Tsung-Ding WANG, Tainan (TW); Wei-Yu CHEN, Hsinchu (TW)

(21) Appl. No.: 19/086,463

(22) Filed: Mar. 21, 2025

(51) Int. Cl. H01L 25/10; H01L 21/56; H01L 23/00; H01L 23/31; H01L 23/367; H01L 23/498; H01L 23/538; H01L 25/065; H10B 80/00

(52) U.S. Cl. CPC H10W 90/00; H10B 80/00; H10W 40/22; H10W 70/611; H10W 74/016; H10W 74/121; H10W 90/401; H10W 90/701; H10W 70/09; H10W 70/60; H10W 70/6528; H10W 90/10; H10W 90/22; H10W 90/288; H10W 90/722; H10W 90/734; H10W 90/736

(57) ABSTRACT

A package structure includes a package substrate, a package module on the package substrate including a first encapsulant layer, an active die in the first encapsulant layer, wherein the active die includes a first area with a first power density and a second area with a second power density and the first power density is greater than the second power density. The package module may further include a dummy die over the first area of the active die, and the package structure may further include a second encapsulant layer on the package substrate around the package module.

### BACKGROUND

Heat dissipation in semiconductor structures may present many challenges. This is particularly the case for an embedded active die in the semiconductor structure. In particular, the embedded active die may be thermally isolated within a molding compound. The molding compound typically has low thermal conductivity, which may trap heat generated by the embedded active die. Heat buildup may lead to thermal stress and degradation of the embedded active die over time.

The embedded active die may also have limited heat pathways. Since the embedded active die is surrounded by the molding compound, the embedded active die may not have direct contact with effective heat sinks or thermal vias. Heat dissipation, therefore, may rely on conduction through the molding compound which is inefficient.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a vertical cross-sectional view of a package structure along line AA′ in FIG. 1D according to one or more embodiments.

FIG. 1B is another vertical cross-sectional view of a package structure along line BB′ in FIG. 1D according to one or more embodiments.

FIG. 1C is a detailed vertical cross-sectional view of a package module in the package structure along line AA′ in FIG. 1D according to one or more embodiments.

FIG. 1D is a plan view (e.g., top-down view) of the package structure according to one or more embodiments.

FIG. 1E is a detailed plan view (e.g., top-down view) of a portion of the package structure according to one or more embodiments.

FIG. 2 is a plan view (top-down view) of a configuration of the embedded active die according to an embodiment of the present invention.

FIG. 3A is a vertical cross-sectional view of an intermediate structure including the embedded active dies on a first carrier substrate according to an embodiment of the present invention.

FIG. 3B is a vertical cross-sectional view of an intermediate structure including the lower molding material layer according to one or more embodiments.

FIG. 3C is a vertical cross-sectional view of an intermediate structure after polishing (e.g., planarizing) the lower molding material layer according to one or more embodiments.

FIG. 3D is a vertical cross-sectional view of an intermediate structure including the upper RDL structure according to one or more embodiments.

FIG. 3E is a vertical cross-sectional view of an intermediate structure including the first semiconductor die and dummy dies on the upper RDL structure according to one or more embodiments.

FIG. 3F is a vertical cross-sectional view of an intermediate structure including the package module underfill layer according to one or more embodiments.

FIG. 3G is a vertical cross-sectional view of an intermediate structure including the upper molding material layer according to one or more embodiments.

FIG. 3H is a vertical cross-sectional view of an intermediate structure after polishing (e.g., planarizing) the upper molding material layer according to one or more embodiments.

FIG. 3I is a vertical cross-sectional view of an intermediate structure including a second carrier substrate on the upper molded portion according to one or more embodiments.

FIG. 3J is a vertical cross-sectional view of an intermediate structure after detaching the first carrier substrate according to one or more embodiments.

FIG. 3K is a vertical cross-sectional view of an intermediate structure including the lower RDL structure according to one or more embodiments.

FIG. 3L is a vertical cross-sectional view of an intermediate structure on a frame mount according to one or more embodiments.

FIG. 3M is a vertical cross-sectional view of an intermediate structure after detaching the second carrier substrate according to one or more embodiments.

FIG. 3N is a vertical cross-sectional view of an intermediate structure including the package module on the package substrate 10 according to one or more embodiments.

FIG. 3O is a vertical cross-sectional view of an intermediate structure including the package underfill layer according to one or more embodiments.

FIG. 3P is a vertical cross-sectional view of an intermediate structure including the outer molding material layer according to one or more embodiments.

FIG. 4 is a flow chart illustrating a method of making the package structure according to one or more embodiments.

FIG. 5A is a vertical cross-sectional view of a package structure along line CC′ in FIG. 5B having the first alternative configuration according to one or more embodiments.

FIG. 5B is a plan view (e.g., top-down view) of the package structure having the first alternative configuration according to one or more embodiments.

FIG. 5C is a detailed plan view (e.g., top-down view) of a portion of the package structure having the first alternative configuration according to one or more embodiments.

FIG. 6A is a vertical cross-sectional view of a package structure along line DD′ in FIG. 6B having the second alternative configuration according to one or more embodiments.

FIG. 6B is a plan view (e.g., top-down view) of the package structure having the second alternative configuration according to one or more embodiments.

FIG. 6C is a detailed plan view (e.g., top-down view) of a portion of the package structure having the second alternative configuration according to one or more embodiments.

FIG. 7 is a vertical cross-sectional view of a package structure having the third alternative configuration according to one or more embodiments.

FIG. 8 is a vertical cross-sectional view of a package structure having the fourth alternative configuration according to one or more embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Heat dissipation difficulties with the embedded active die may also result in hotspot formation in a semiconductor structure. In particular, the embedded active die may generate uneven heat distributions due to varying activity levels across different regions of the embedded active die. This may lead to the formation of localized hotspots within the semiconductor structure.

In addition, limited heat dissipation from the embedded active die may also cause thermal coupling with surrounding elements of the semiconductor structure. In particular, heat generated by the embedded active die may cause a temperature increase in the surrounding elements. The increased temperature may impact the performance or reliability of the surrounding elements.

Semiconductor manufacturers have used several different solutions to address heat dissipation challenges of embedded active dies. In some cases, enhanced molding compounds may be used. In particular, thermally conductive molding compounds may be used to improve heat conduction from the embedded active die to an external heat sink. Materials such as filled epoxies with additives like aluminum nitride or boron nitride may enhance the thermal conductivity of the molding compound.

Thermal Interface Materials (TIMs) may also be used by manufacturers. The TIM may be placed between the embedded active die and adjacent structures to improve thermal contact and heat transfer. The TIMs may include materials such as thermal grease, pads, or phase-change materials optimized for the particular semiconductor structure.

In some cases, an integrated heat spreader may be used to dissipate the heat generated by active dies and components in a semiconductor package. In particular, a heat spreader layer, such as a thin metal plate (e.g., copper or aluminum), may be formed within the molding compound to distribute the heat uniformly. The heat spreader layer may also direct the heat toward a heat sink.

Heat dissipation may also be improved by incorporating thermal vias into the molding compound. In particular, the thermal vias may be formed in the molding compound to connect the embedded active die to heat-dissipating structures such as a package substrate or heat sink. The thermal vias may be designed with a low thermal resistance to enhance heat flow.

Power management techniques may also be used to reduce heat generation by the embedded active die. In particular, thermal throttling may be used to dynamically adjust the performance of the embedded active die based on temperature thresholds.

The heat generated by an embedded active die may especially impact any semiconductor dies located above the embedded active die. In particular, the heat from the embedded active die may impact the performance or reliability of the semiconductor dies above the embedded active die. For example, an embedded active die located under a high bandwidth memory (HBM) device may impact the thermal behavior of the HBM device. The HBM device may include a stack of memory dies (e.g., memory die stack, stacked structure of memory dies, etc.). In particular, heat from the embedded active die may cause a temperature of the HBM device to increase to a point the cause a diminished performance of the HBM device.

At least one embodiment of the present disclosure may provide a dummy die design (e.g., dummy silicon design) to improve the thermal behavior of a semiconductor device (e.g., HBM device) above or near the embedded active die. At least one embodiment may include a novel thermal dissipation structure as a thermal solution for embedded active dies in a semiconductor structure (e.g., chip-on-wafer-on-substrate structure).

In at least one embodiment, the embedded active die includes a first area with a first power density and a second area with a second power density. The first power density is greater than the second power density. In at least one embodiment, the first power density may be greater than 0.1 W/mm². In at least one embodiment, the first power density may be greater than 0.2 W/mm². In at least one embodiment, the first power density may be greater than 0.9 W/mm². In at least one embodiment, the first area is a highest power density area (e.g., maximum power density area) of the embedded active die and may be located away from an HBM device. A dummy die (e.g., dummy silicon) may be located over the first area (e.g., highest power density area). The HBM device may be located at a position other than over the first area of the embedded active die. With this configuration, a temperature of the HBM device may be decreased. The configuration may, therefore, result in an improved performance and reliability of the HBM device.

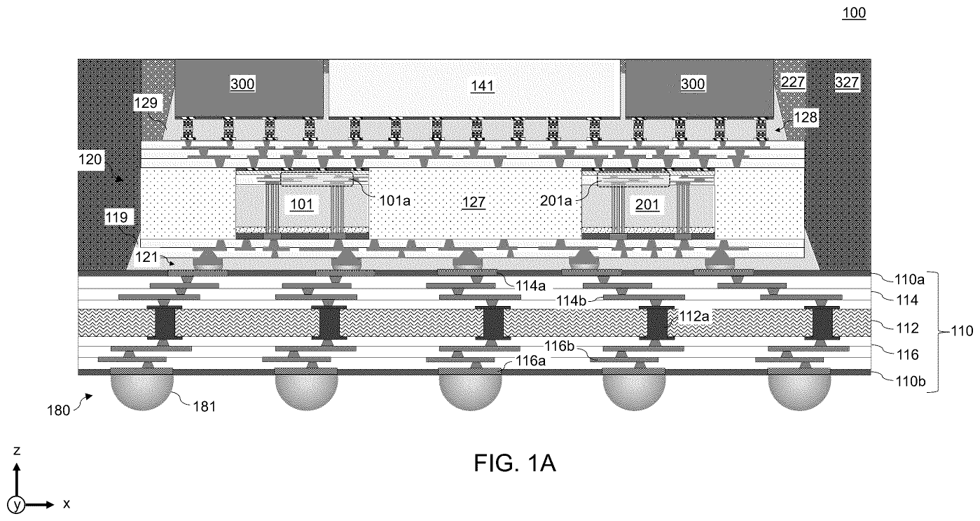

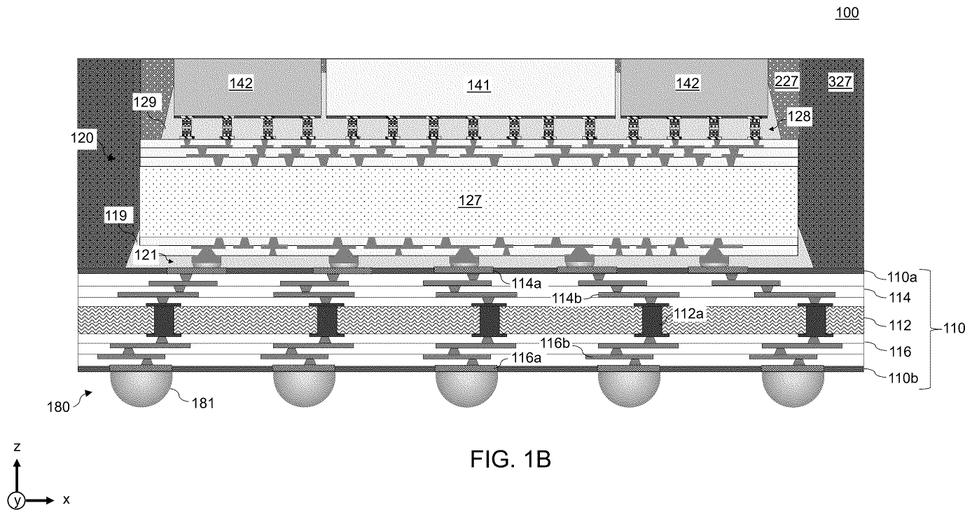

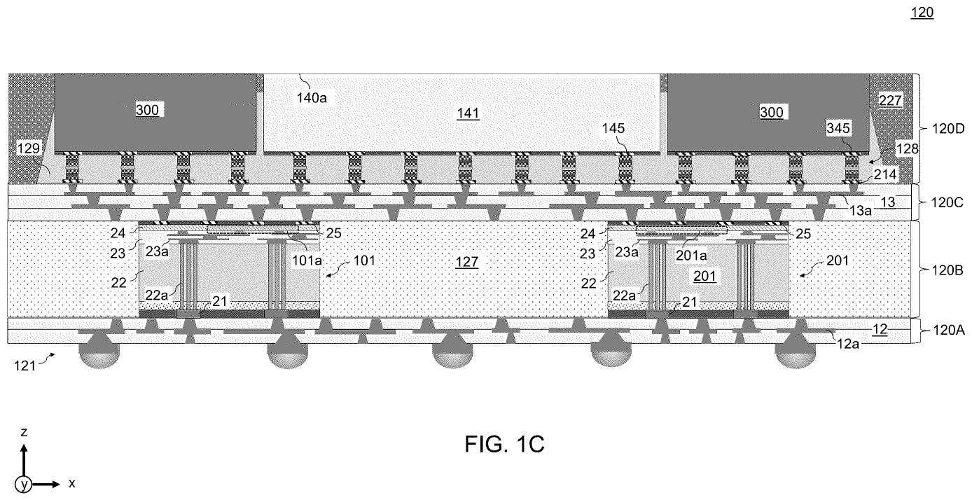

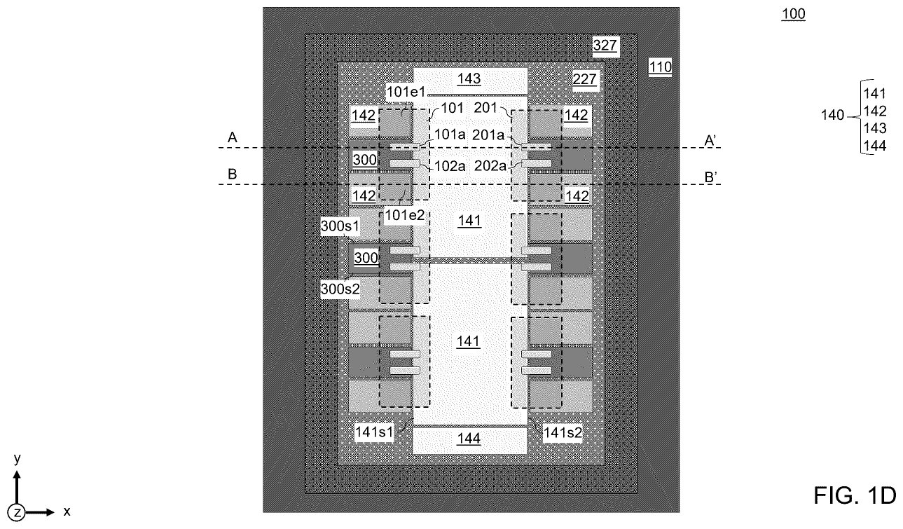

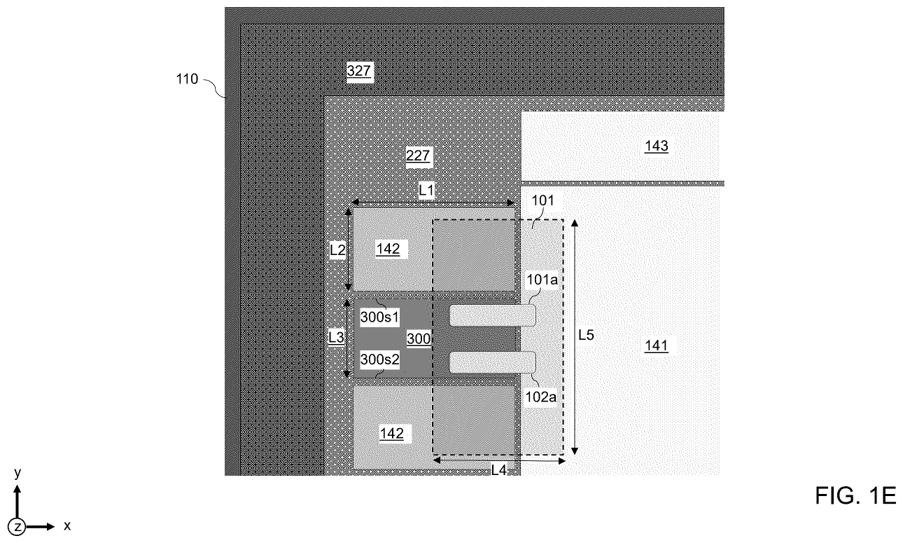

FIG. 1A is a vertical cross-sectional view of a package structure 100 according to one or more embodiments. FIG. 1B is another vertical cross-sectional view of a package structure 100 according to one or more embodiments. FIG. 1C is a vertical cross-sectional view of a package module 120 in the package structure 100 according to one or more embodiments. FIG. 1D is a plan view (e.g., top-down view) of the package structure 100 according to one or more embodiments. The vertical cross-sectional views in FIGS. 1A and 1C are along the line A-A′ in FIG. 1D and the vertical cross-sectional views in FIG. 1B is along the line B-B′ in FIG. 1D. FIG. 1E is a detailed plan view (e.g., top-down view) of a portion of the package structure 100 according to one or more embodiments.

As illustrated in FIG. 1A, the package structure 100 may include a package substrate 110 and a package module 120 on the package substrate 110. The package module 120 may include one or more active dies 101, 201 in a first molding material layer 127 (e.g., first encapsulant layer). The active dies 101, 201 may be referred to as “embedded active dies 101, 201”. The package module 120 may also include one or more dummy dies 300 over the embedded active dies 101, 201. The package structure 100 may also include an outer molding material layer 327 (e.g., second encapsulant layer) on the package substrate 110 around the package module 120.

The embedded active die 101 may include a highest power density area 101a. The embedded active die 201 may include a highest power density area 201a. The dummy dies 300 may be located over the highest power density areas of the embedded active die 101 (e.g., highest power density area 101a) and the highest power density areas of the embedded active die 201 (e.g., highest power density area 201a). It should be noted that the term “embedded active die” may be understood to mean that an active die that is at least partly surrounded by the first molding material layer 127.

The package module 120 may further include one or more semiconductor dies 140 including one or more first semiconductor dies 141 (e.g., primary dies) and one or more second semiconductor dies 142 (see FIGS. 1B and 1D). The second semiconductor dies 142 may include, for example, a high bandwidth memory (HBM) device. The second semiconductor dies 142 may be located separate from the highest power density areas of the embedded active dies 101 (e.g., highest power density area 101a) and separate from the highest power density areas of the embedded active dies 201 (e.g., highest power density area 201a), and the dummy dies 300 may be located over the highest power density areas. With this configuration, during an operation of the package structure 100, a temperature of the second semiconductor dies 142 (e.g., HBM devices) may be significantly decreased compared to a conventional configuration. In at least one embodiment, an operating temperature of the second semiconductor dies 142 (e.g., HBM devices) may be less than 115° C. (e.g., about 106.8° C.). The configuration may, therefore, result in an improved performance and reliability of the second semiconductor dies 142.

As further illustrated in FIG. 1A, the package substrate 110 may include a cored or coreless substrate. In at least one embodiment, for example, the package substrate 110 may include a core 112, a package substrate upper dielectric layer 114 formed on the core 112 (e.g., a first side or chip-side of the package substrate 110), and a package substrate lower dielectric layer 116 formed on the core 112 (e.g., a second side or board-side of the package substrate 110). In particular, the package substrate 110 may include a build-up film substrate such as an Ajinomoto build-up film (ABF) substrate. That is, in at least one embodiment, each of the package substrate upper dielectric layer 114 and the package substrate lower dielectric layer 116 may be described as an ABF layer.

The core 112 may help to provide rigidity to the package substrate 110. The core 112 may include, for example, an epoxy resin such as a bismaleimide triazine epoxy (BT epoxy) and/or a woven glass laminate. The core 112 may alternatively or in addition include an organic material such as a polymer material. In particular, the core 112 may include a dielectric polymer material such as polyimide (PI), benzocyclobutene (BCB), or polybenzobisoxazole (PBO). Other suitable dielectric materials are within the contemplated scope of disclosure.

The core 112 may include one or more through vias 112a. The through vias 112a may extend from a lower surface of the core 112 to an upper surface of the core 112. The through vias 112a may allow an electrical connection between the package substrate upper dielectric layer 114 and the package substrate lower dielectric layer 116. The through vias 112a may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The package substrate upper dielectric layer 114 may be formed on an upper surface of the core 112. The package substrate upper dielectric layer 114 may include a plurality of layers and, in particular, may include a build-up film (e.g., ABF). The package substrate upper dielectric layer 114 may also include an organic material such as a polymer material. In particular, the package substrate upper dielectric layer 114 may include a dielectric polymer material such as polyimide (PI), benzocyclobutene (BCB), or polybenzobisoxazole (PBO). Other suitable dielectric materials are within the contemplated scope of disclosure.

The package substrate upper dielectric layer 114 may include one or more package substrate upper bonding pads 114a on a chip-side surface of the package substrate upper dielectric layer 114. In particular, the package substrate upper bonding pads 114a may be exposed on the chip-side surface of the package substrate upper dielectric layer 114. The package substrate upper dielectric layer 114 may also include one or more metal interconnect structures 114b. The metal interconnect structures 114b may be connected to the package substrate upper bonding pads 114a and the through vias 112a in the core 112. The metal interconnect structures 114b may include a plurality of metal layers (e.g., copper traces) and a plurality of metal vias connecting the metal layers. The package substrate upper bonding pads 114a and the metal interconnect structures 114b may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

A package substrate upper passivation layer 110a may be formed on the chip-side surface of the package substrate upper dielectric layer 114. The package substrate upper passivation layer 110a may partially cover the package substrate upper bonding pads 114a. The package substrate upper passivation layer 110a may include silicon oxide, silicon nitride, low-k dielectric materials such as carbon-doped oxides, extremely low-k dielectric materials such as porous carbon doped silicon dioxide, a combination thereof or other suitable material.

The package substrate lower dielectric layer 116 may be formed on an lower surface of the core 112. The package substrate lower dielectric layer 116 may also include a plurality of layers and, in particular, may include a build-up film (e.g., ABF). The package substrate lower dielectric layer 116 may also include an organic material such as a polymer material. In particular, the package substrate lower dielectric layer 116 may include a dielectric polymer material such as polyimide (PI), benzocyclobutene (BCB), or polybenzobisoxazole (PBO). Other suitable dielectric materials are within the contemplated scope of disclosure.

The package substrate lower dielectric layer 116 may include one or more package substrate lower bonding pads 116a on a board-side surface of the package substrate lower dielectric layer 116. In particular, the package substrate lower bonding pads 116a may be exposed on the board-side surface of the package substrate lower dielectric layer 116. The package substrate lower dielectric layer 116 may also include one or more metal interconnect structures 116b. The metal interconnect structures 116b may be connected to the package substrate lower bonding pads 116a and the through vias 112a in the core 112. The metal interconnect structures 116b may include a plurality of metal layers (e.g., copper traces) and a plurality of metal vias connecting the metal layers. The package substrate lower bonding pads 116a and the metal interconnect structures 116b may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

A package substrate lower passivation layer 110b may be formed on the board-side surface of the package substrate lower dielectric layer 116. The package substrate lower passivation layer 110b may partially cover the package substrate lower bonding pads 116a. The package substrate lower passivation layer 110b may include silicon oxide, silicon nitride, low-k dielectric materials such as carbon-doped oxides, extremely low-k dielectric materials such as porous carbon doped silicon dioxide, a combination thereof or other suitable material.

A ball-grid array (BGA) 180 including a plurality of solder balls 181 may be formed on the board-side surface of the package substrate lower dielectric layer 116. The solder balls 181 of the BGA 180 may allow the package structure 100 to be securely mounted on a substrate such as a printed circuit board (PCB) and electrically coupled to the substrate. The solder balls 181 may contact the package substrate lower bonding pads 116a, respectively. The solder balls 181 may therefore be electrically connected to the package substrate upper bonding pads 114a by way of the package substrate lower bonding pads 116a, metal interconnect structures 116b, the through vias 112a and the metal interconnect structures 114b.

The package module 120 may be connected to the package substrate 110 by a plurality of C4 bumps 121 on the board-side surface of the package module 120. The C4 bumps 121 may be bonded to the package substrate upper bonding pads 114a in the package substrate 110. The C4 bumps 121 may be bonded to the package substrate upper bonding pads 114a by using, for example, solder reflow, compression bonding, thermo-compression bonding, etc. The C4 bumps 121 may include a metal pillar (e.g., copper pillar) and a solder bump (e.g., SnAg solder bump) on the metal pillar. In at least one embodiment, the solder bump may be collapsed to join the metal pillar of the C4 bump 121 to the package substrate upper bonding pads 114a.

A package underfill layer 119 may be formed on the package substrate 110 under and around the package module 120. The package underfill layer 119 may also be formed around the C4 bumps 121. The package underfill layer 119 may thereby securely fix the package module 120 to the package substrate 110. The package underfill layer 119 may be formed of an underfill material such as an epoxy-based polymeric material. Other suitable materials may be used for the package underfill layer 119.

The outer molding material layer 327 may be formed on and around the package underfill layer 119 that is under and around the package module 120. An upper surface of the outer molding material layer 327 may be substantially coplanar with an upper surface of the package module 120. The outer molding material layer 327 may include, for example, a polymeric material and in particular, an epoxy-based polymeric material (e.g., EMC). Other suitable material may be used in the outer molding material layer 327.

FIG. 1C is a detailed vertical cross-sectional view of a package module in the package structure along line AA′ in FIG. 1D according to one or more embodiments. Referring again to FIG. 1C, the package module 120 may include a lower RDL structure 120A and a lower molded portion 120B on the lower RDL structure 120A. The package module 120 may also include an upper RDL structure 120C on the lower molded portion 120B and an upper molded portion 120D on the upper RDL structure 120C.

In at least one embodiment, the lower RDL structure 120A may include a plurality of polymer layers 12 and a plurality of redistribution layers 12a stacked alternately. The number of the polymer layers 12 and/or the number of redistribution layers 12a in the lower RDL structure 120A are not limited by the disclosure.

In at least one embodiment, the polymer layers 12 may include, for example, polyimide (PI), epoxy resin, acrylic resin, phenol resin, benzocyclobutene (BCB), polybenzoxazole (PBO), or any other suitable polymer-based dielectric material. In some embodiments, the redistribution layers 12a may include conductive materials. The conductive materials may include metal such as copper, aluminum, nickel, titanium, a combination thereof. Other suitable conductive materials may be within the contemplated scope of disclosure.

The redistribution layers 12a may include metallic connection structures, i.e., metallic structures that provide electrical connection between nodes in the structure. The redistribution layers 12a may include a metallic seed layer and a metallic fill material on the metallic seed layer. The metallic seed layer may include, for example, a stack of a titanium barrier layer and a copper seed layer. The titanium barrier layer may have thickness in a range from 50 nm to 500 nm, and the copper seed layer may have a thickness in a range from 50 nm to 500 nm, although lesser or greater thicknesses may also be used. The metallic fill material for the redistribution layers 12a may include copper, nickel, or copper and nickel. Other suitable metallic fill materials are within the contemplated scope of disclosure. The thickness of the metallic fill material that is deposited for each redistribution layers 12a may be in a range from 2 microns to 40 microns, such as from 4 microns to 10 microns, although lesser or greater thicknesses may also be used.

In at least one embodiment, the redistribution layers 12a may include a plurality of traces (lines) and a plurality of vias connecting the plurality traces to each other. The traces may be respectively located on the polymer layers 12, and may extend in the x-direction (first horizontal direction) and y-direction (second horizontal direction) on a surface (e.g., a lower surface) of the polymer layers 12. The C4 bumps 121 may be formed on a board-side surface of the lower RDL structure 120A. The C4 bumps 121 may be electrically coupled to the redistribution layers 12a.

The lower molded portion 120B may be formed on the lower RDL structure 120A. The lower molded portion 120B may have a length in the x-direction that is substantially the same as a length in the x-direction of the lower RDL structure 120A. The lower molded portion 120B may have a width in the y-direction that is substantially the same as a width in the y-direction of the lower RDL structure 120A. The lower molded portion 120B may have a thickness in the z-direction greater than a thickness of the lower RDL structure 120A.

The lower molded portion 120B may include the lower molding material layer 127 (e.g., first encapsulant layer) formed on the lower RDL structure 120A. In at least one embodiment, the lower molding material layer 127 may be formed of a curable material that may cure to form a hard, solid structure. The lower molding material layer 127 may include, for example, epoxy molding compound (EMC). In at least one embodiment, the lower molding material layer 127 may include a polymeric material and in particular, an epoxy-based polymeric material. Other suitable molding materials may be used.

In at least one embodiment, the lower molding material layer 127 may have a coefficient of thermal expansion (CTE) that is substantially similar to a CTE of the lower RDL structure 120A. In at least one embodiment, the lower molding material layer 127 may include an added material (e.g., filler material) for improving a property of the lower molding material layer 127 (e.g., thermal conductivity, CTE, etc.). The added material may include, for example, metal powder, metal oxide powder, etc. Other materials in the lower molding material layer 127 are within the contemplated scope of the disclosure.

The lower molded portion 120B of the package module 120 may also include one or more embedded active dies 101, 201. The embedded active dies 101, 201 may be mounted on the lower RDL structure 120A. The embedded active dies 101 may have a structure and function similar to a structure and function of the embedded active dies 201 or different than a structure and function of the embedded active dies 201.

The embedded active dies 101, 201 may be surrounded (e.g., at least in the x-direction and y-direction) by the lower molding material layer 127. In at least one embodiment, the lower molding material layer 127 may contact a substantial entirety of the sidewalls of the embedded active dies 101, 201 (e.g., the embedded active dies 101, 201 may be substantially embedded in the lower molding material layer 127. The embedded active dies 101, 201 may interconnect the primary semiconductor dies 141 and second semiconductor dies 142 (see FIGS. 1B and 1D). In particular, the embedded active dies 101, 201 may interconnect (e.g., electrically couple) a first semiconductor die 141 to one or more second semiconductor dies 142.

The embedded active dies 101, 201 may include lower contact pads 21 (e.g., metal contact pads) electrically coupled to the redistribution layers 12 in the lower RDL structure 120A. The embedded active dies 101, 201 may also include a bulk semiconductor region 22 including one or more through silicon vias (TSVs) 22a. The bulk semiconductor region 22 may include a semiconductor material such as silicon, germanium, etc. The TSVs 22a may be electrically coupled to the lower contact pads 21.

The embedded active dies 101, 201 may also include a redistribution portion 23 including redistribution layers 23a on the bulk semiconductor region 22. The redistribution portion 23 including the redistribution layers 23a may have a structure substantially similar to a structure of the lower RDL structure 120A. The embedded active dies 101, 201 may also include an active region 24 that may include one or more active devices such as transistors, diodes, thyristors, etc. The active region 24 may be electrically coupled to the TSVs 22a through the redistribution layers 23a of the redistribution portion 23. The active region 24 of the embedded active die 101 may include the highest power density areas of the embedded active die 101 (e.g., highest power density area 101a) and the active region 24 of the embedded active die 201 may include the highest power density areas of the embedded active die 201 (e.g., highest power density area 101a).

It should be noted that areas of the embedded active dies 101, 201 may include varying levels of power density. The highest power density area 101a may have the highest power density (maximum power density) in the embedded active die 101. The highest power density area 201a may have the highest power density (maximum power density) in the embedded active die 201.

The embedded active dies 101, 201 may also include one or more upper contact pads 25 (e.g., metal contact pads) electrically coupled to the active region 24. The upper contact pads 25 may allow the active region 24 to be electrically coupled to the semiconductor dies 140 above the embedded active dies 101, 201. Each of the lower contact pads 21, the TSVs 22a, the redistribution layers 23a in the redistribution portion 23, and the upper bonding pads 25 may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The lower molded portion 120B may also integrate additional elements, such as one or more stand-alone IPDs (not shown). In at least one embodiment, the IPDs may be located in the lower molding material layer 127 underneath one or more of the semiconductor dies 140 to support signal communication.

Referring again to FIG. 1C, the upper RDL structure 120C of the package module 120 may have a structure substantially similar to that of the lower RDL structure 120A. In particular, the upper RDL structure 120C may include a plurality of polymer layers 13 and a plurality of redistribution layers 13a stacked alternately. The number of the polymer layers 13 and/or the number of redistribution layers 13a in the upper RDL structure 120C are not limited by the disclosure. The materials that may be used in the polymer layers 13 may be substantially the same as the materials that may be used in the polymer layers 12. The materials that may be used in the redistribution layers 13a may bs substantially the same as the materials that may be used in the redistribution layers 12a. The structure (e.g., thickness) of the redistribution layers 13a may be substantially the same as the structure of the redistribution layers 12a.

The redistribution layers 13a in the upper RDL structure 120C may contact the upper contact pads 25 of the embedded active dies 101, 201 in the lower molded portion 120B. The redistribution layers 13a may be electrically coupled to the redistribution layers 12a in the lower RDL structure 120A by the embedded active dies 101, 201.

The upper RDL structure 120C may also include a plurality of bonding pads 214 on an upper surface of the upper RDL structure 120C. The bonding pads 214 may be substantially similar to the lower contact pads 21 and the upper contact pads 25 in the embedded active dies 101, 201. In particular, the materials that may be used in the bonding pads 214 may be substantially the same as the materials that may be used in the lower contact pads 21 and the upper contact pads 25. As illustrated in FIG. 1C, the upper molded portion 120D of the package module 120 may be formed on the upper RDL structure 120C. The upper molded portion 120D may include the semiconductor dies 140 and the dummy dies 300. The dummy dies 300 may have a thermal conductivity of at least 120 W/m•K. The dummy dies 300 may include, for example, a silicon dummy die 300. In at least one embodiment, the dummy dies 300 may include at least one of silicon, silicon carbide, gallium nitride, aluminum nitride, boron nitride, graphite or silicon nitride. Other suitable materials for use in the dummy die are within the contemplated scope of disclosure.

The semiconductor dies 140 may include die bonding pads 145 and the dummy dies 300 may include die bonding pads 345. The die bonding pads 145 and the die bonding pads 345 may be connected to the bonding pads 214 on the upper surface of the upper RDL structure 120C by a plurality of die connection structures such as microbumps 128. The microbumps 128 may each include a lower portion on the bonding pads 214 and an upper portion on the die bonding pads 145 of the semiconductor dies 140 and die bonding pads 345 of the dummy dies 300. Each of the lower portion and upper portion of the microbumps 128 may include a copper post and one or more additional metal layers (e.g., nickel layers, copper layers). The lower portion and upper portion of the microbumps 128 may be connected by a solder joint. The microbumps 128 may be electrically coupled to the embedded active dies 101, 201 by the upper RDL structure 120C.

The package module 120 may also include a package module underfill layer 129 that is formed (e.g., individually or collectively) under and around each of the semiconductor dies 140 and dummy dies 300. The package module underfill layer 129 may also be formed around the microbumps 128. The package module underfill layer 129 may thereby fix each of the semiconductor dies 140 and the dummy dies 300 to the upper RDL structure 120C. The package module underfill layer 129 may be formed of an epoxy-based polymeric material.

Each of the semiconductor dies 140 may include, for example, a singular semiconductor die, a system on chip (SOC) die, or a system on integrated chips (SoIC) die, and may be implemented by chip on wafer on substrate (CoWoS) technology or integrated fan-out on substrate (INFO-oS) technology. In particular, each of the semiconductor dies 140 may include, for example, a semiconductor chip or chiplet for a high performance computing (HPC) application, an artificial intelligence (AI) application, and a 5G cellular network application, a logic die (e.g., mobile application processor, microcontroller, etc.), an optical die or a memory die (e.g., high-bandwidth memory (HBM) device, hybrid memory cube (HMC), dynamic random access memory (DRAM) die, a Wide I/O die, a M-RAM die, a R-RAM die, an inverted AND (NAND) die, static random access memory (SRAM), etc. ), a central processing unit (CPU) chip, graphics processing unit (GPU) chip, field-programmable gate array (FPGA) chip, networking chip, application-specific integrated circuit (ASIC) chip, artificial intelligence/deep neural network (AI/DNN) accelerator chip, etc., a co-processor, accelerator, an on-chip memory buffer, a high data rate transceiver die, a I/O interface die, an integrated passive device (IPD) die, a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) die), a monolithic 3D heterogeneous chiplet stacking die, etc. Other dies are within the contemplated scope of this disclosure. In at least one embodiment, the first semiconductor die 141 may include a primary die (e.g., SoC die), and the second semiconductor die 142 may include an ancillary die (e.g., memory/SoC die, HBM device, etc.).

The package module 120 may also include an upper molding material layer 227 formed around the semiconductor dies 140 and the dummy dies 300. The upper molding material layer 227 may also be formed on and around the package module underfill layer 129. The upper molding material layer 227 may have an outer sidewall that is substantially aligned with an outer sidewall of the polymer layers 13 in the upper RDL structure 120C, an outer sidewall of the lower molding material layer 127 and an outer sidewall of the polymer layers 12 in the lower RDL structure 120A.

In at least one embodiment, the upper molding material layer 227 may be formed on sidewalls (inner sidewall and outer sidewall) of each of the semiconductor dies 140 and the dummy dies 300. In at least one embodiment, an upper surface of the package module underfill layer 129 may be recessed from upper surface of the semiconductor dies 140a and dummy dies 300. In that case, the upper molding material layer 227 may be formed on the upper surface of the package module underfill layer 129 between the semiconductor dies 140 and dummy dies 300. The upper molding material layer 227 may be formed between and bonded to the sidewalls of each of the semiconductor dies 140 and the dummy dies 300. The upper molding material layer 227 may also be bonded to the chip-side surface of the upper RDL structure 120C and the package module underfill layer 129.

As illustrated in FIG. 1C, the upper molding material layer 227 may include an upper surface that is substantially coplanar with the upper surface 140a of the semiconductor dies 140 and dummy dies 300. The upper surface of the upper molding material layer 227 may alternatively or additionally include a recessed upper surface (not shown) that is recessed in the z-direction from the upper surface 140a of the semiconductor dies 140. In at least one embodiment, the recessed upper surface may constitute an entirety of an upper surface of the upper molding material layer 227.

In at least one embodiment, the upper molding material layer 227 may be formed of a curable material that may cure to form a hard, solid structure. The upper molding material layer 227 may include, for example, epoxy molding compound (EMC). In at least one embodiment, the upper molding material layer 227 may include a material that is substantially similar to the package module underfill layer 129, and or substantially similar to the lower molding material layer 127 in the lower molded portion 120B. In at least one embodiment, the upper molding material layer 227 may include a polymeric material and in particular, an epoxy-based polymeric material. Other suitable molding materials may be within the contemplated scope of disclosure.

In at least one embodiment, the upper molding material layer 227 may have a CTE that is substantially similar to a CTE of the upper RDL structure 120C, a CTE of the lower molded portion 120B and/or a CTE of the lower RDL structure 120A. In at least one embodiment, the upper molding material layer 227 may include an added material (e.g., filler material) for improving a property of the upper molding material layer 227 (e.g., thermal conductivity, CTE, etc.). The added material may include, for example, metal powder, metal oxide powder, etc. Other materials in the upper molding material layer 227 are within the contemplated scope of the disclosure.

Referring again to FIG. 1D, a location of the embedded active dies 101, 201 beneath the semiconductor dies 140 are shown as shadows in FIG. 1D. The embedded active die 101 may include the high power density area 101a and the high power density area 102a. The embedded active die 201 may include the highest power density area 201a and the highest power density area 202a.

The one or more second semiconductor dies 142 may be located on a side of the one or more first semiconductor dies 141 in a first direction (x-direction). The first semiconductor dies 141 may be substantially aligned in a second direction (y-direction) perpendicular to the first direction. In at least one embodiment, the second semiconductor dies 142 may include a first column of the second semiconductor dies 142 on a first side 141s1 of the first semiconductor dies 141 and a second column of the second semiconductor dies 142 on a second side 141s2 of the first semiconductor dies 141. Each of the first column of the second semiconductor dies 142 and the second column of the second semiconductor dies 142 may include the second semiconductor dies 142 substantially aligned in the second direction (y-direction).

The semiconductor dies 140 may also include other second semiconductor dies 143 and 144. The second semiconductor dies 143 and 144 may be substantially aligned in the second direction with the first semiconductor dies 141. The second semiconductor dies 143 and 144 may have a structure and function similar to a structure and function of the second semiconductor dies 142 or different than a structure and function of the second semiconductor dies 142. Although the package module 120 is illustrated as including a particular number of semiconductor dies having a particular arrangement, the number of semiconductor dies and the arrangement of the semiconductor dies is not limited to any particular number and arrangement. In particular, the package structure 100 may include any number and arrangement of semiconductor dies.

For ease of understanding, the description of the package structure 100 in FIG. 1D may at times be limited to the structure on the first side 141s1 of the first semiconductor dies 141. It should be noted that the structure on the second side 141s2 of the first semiconductor dies 141 may be substantially the same as the structure on the first side 141s1 of the first semiconductor dies 141. Thus, the description with respect to the first side 141s1 of the first semiconductor dies 141 may be understood to apply equally to the structure on the second side 141s2 of the first semiconductor dies 141.

As illustrated in FIG. 1D, the first semiconductor die 141 may extend lengthwise in the second direction (y-direction). The embedded active die 101 may also extend lengthwise in the second direction. The dummy die 300 may include a dummy die first side 300s1 on a side of the dummy die 300 facing the second direction. The embedded active die 101 may include a first end 101e1 (e.g., top half) in the second direction. The first end 101e1 of the embedded active die 101 may constitute about one-half the area of the embedded active die 101 in the second direction. The first end 101e1 of the embedded active die 101 may be under a second semiconductor die 142 located on the dummy die first side 300s1. The first end 101e1 may be dedicated to (associated with) the second semiconductor die 142 located on the dummy die first side 300s1. The first end 101e1 may include the highest power density area 101a which is located under the dummy die 300.

The dummy die 300 may also include a dummy die second side 300s2 opposite the dummy die first side 300s1 in the second direction. The embedded active die 101 may also include a second end 101e2 (e.g., bottom half) opposite the first end 101e1 in the second direction. The second end 101e2 of the embedded active die 101 may also constitute about one-half the area of the embedded active die 101 in the second direction. The second end 101e2 of the embedded active die 101 may be under a second semiconductor die 142 located on the dummy die second side 300s2. The second end 101e2 of the embedded active die 101 may be dedicated to (associated with) the second semiconductor die 142 located on the dummy die second side 300s2. The second end 101e2 of the embedded active die 101 may include the highest power density area 102a which is also located under the dummy die 300.

The highest power density area 101a in the first end 101e1 of the embedded active die 101 may be adjacent the highest power density area 102a in the second end 101e2 of the embedded active die 101 in the second direction. In at least one embodiment, the highest power density area 101a may be substantially aligned with the highest power density area 102a in the second direction.

The first semiconductor die 141 may be adjacent the dummy die 300 in the first direction, adjacent the second semiconductor die 142 on the dummy die first side 300s1 of the dummy die 300 in the first direction and adjacent the second semiconductor die 142 on the dummy die second side 300s2 of the dummy die 300 in the first direction. At least a portion of the embedded active die 101 may be located beneath each of the first semiconductor die 141, the dummy die 300, the second semiconductor die 142 on the dummy die first side 300s1 of the dummy die 300 and the second semiconductor die 142 on the dummy die second side 300s2 of the dummy die 300.

Referring to FIG. 1E, the dummy die 300 may extend lengthwise in the first direction (x-direction). The dummy die 300 may be located between the second semiconductor dies 142 in the second direction. The second semiconductor dies 142 may have a length L1 in the first direction and a length L2 in the second direction. A length of the dummy die 300 in the first direction may be substantially the same as the length L1 of the second semiconductor dies 142. In at least one embodiment, the length of the dummy die 300 in the first direction may be in a range from 80% to 120% of the length L1 of the second semiconductor dies 142.

The dummy die 300 may include a length L3 in the second direction that is less than the length L2 of the second semiconductor dies 142 in the second direction. In at least one embodiment, the length L3 of the dummy die 300 may be no more than 60% of the length L2 of the second semiconductor dies 142.

The embedded active die 101 may have a length L4 in the first direction (x-direction). The length L4 of the embedded active die 101 may be less than or greater than a length L1 of the second semiconductor dies 142. In at least one embodiment, the embedded active die 101 may extend under an entire length L1 of the second semiconductor die 142 on the dummy die first side 300s1 of the dummy die 300 and the second semiconductor die 142 on the dummy die second side 300s2 of the dummy die 300. The embedded active die 101 may traverse a gap between the first semiconductor die 101 and the dummy die 300 and a gap between the first semiconductor die 101 and the second semiconductor dies 142. At least 20% of the length L4 of the embedded active die 101 may be located under the first semiconductor die 141. At least 50% of the length L4 of the embedded active die 101 may be located under the second semiconductor dies 142.

The embedded active die 101 may have a length L5 in the second direction (y-direction). A center of the embedded active die 101 in the second direction may be substantially aligned with a center of the dummy die 300 in the second direction. The embedded active die 101 may extend under the entire length L3 of the dummy die 300 in the second direction. The embedded active die 101 may extend in the second direction under at least 75% of the length L2 of the second semiconductor die 142 on the dummy die first side 300s1 of the dummy die 300 and at least 75% of the second semiconductor die 142 on the dummy die second side 300s2 of the dummy die 300. The length L5 of the embedded active die 101 may be at least 70% of a combination of the length L3 of the dummy die 300 and the length L2 of the second semiconductor die 142 on the dummy die first side 300s1 of the dummy die 300 and the length L2 of the second semiconductor die 142 on the dummy die second side 300s2 of the dummy die 300 (e.g., L5≥0.7(L3+2L2)).

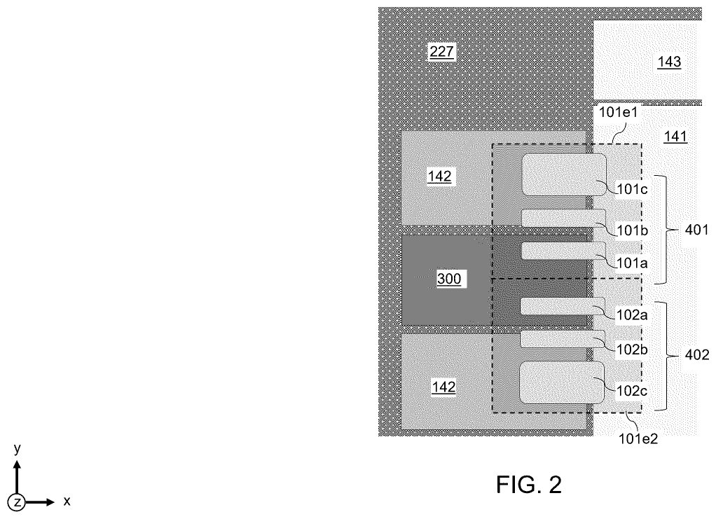

FIG. 2 is a plan view (top-down view) of a configuration of the embedded active die 101 according to an embodiment of the present invention. It should be noted that the embedded active die 201 may have a similar configuration to the configuration of embedded active die 101 in FIG. 2.

In at least one embodiment, the embedded active die 101 may be designed so that the power density in the first end 101e1 is concentrated primarily in the highest power density area 101a. The embedded active die 101 may also be designed so that the power density in the second end 101e2 is concentrated primarily in the highest power density area 102a. In operation, each of the highest power density area 101a and the highest power density area 102a may be the hottest part of the embedded active die 101.

As illustrated in FIG. 2, the first end 101e1 of the embedded active die 101 may have a plurality of power density areas 401. The high power density areas 401 may include the highest power density area 101a (first area) in the first end 101e1, a first lower power density area 101b (e.g., lower than the power density of the highest power density area 101a) in the first end 101e1 and a second lower power density area 101c (e.g., lower than the power density of the first lower power density area 101b) in the first end 101e1. Each of the first lower power density area 101b and second lower power density area 101c may be referred to as a “second area” having a power density less than the power density of a first area (the highest power density area 101a). As illustrated in FIG. 2, a second semiconductor die 142 may be located over the second area (e.g., over the first lower power density area 101b and second lower power density area 101c).

The second end 101e2 of the embedded active die 101 may have a plurality of power density areas 402. The power density areas 402 may include the highest power density area 102a (first area) in the second end 101e2, a first lower power density area 102b (e.g., lower than the power density of the highest power density area 102a) in the second end 101e2 and a second lower power density area 102c (e.g., lower than the power density of the first lower power density area 102b) in the second end 101e2. Each of the first lower power density area 102b and second lower power density area 102c may be referred to as a “second area” having a power density less than the power density of a first area (the highest power density area 102a). As illustrated in FIG. 2, a second semiconductor die 142 may be located over the second area (e.g., over the first lower power density area 102b and second lower power density area 102c).

A power density level (e.g., in W/mm²) of the highest power density area 101a may be substantially the same as a power density level of the highest power density area 102a. A power density level of the first lower power density area 101b may be substantially the same as a power density level of the first lower power density area 102b. A power density level of the second lower power density area 101c may be substantially the same as a power density level of the second lower power density area 102c.

In at least one embodiment, a power density level of the highest power density area 101a in the first end 101e1 and a power density level of the highest power density area 102a in the second end 101e2 may be in a range from 0.80 W/mm² to 1.10 W/mm² (e.g., about 0.94 W/mm²). The power density level of the highest power density area 101a in the first end 101e1 may be at least 1.5 times the power density level of the first lower power density area 101b in the first end 101e1. The power density level of the highest power density area 102a in the second end 101e2 may be at least 1.5 times the power density level of the first lower power density area 102b in the second end 101e2.

A power density level of the first lower power density area 101b in the first end 101e1 and a power density level of the first lower power density area 102b in the second end 101e2 may be in a range from 0.40 W/mm² to 0.70 W/mm² (e.g., about 0.55 W/mm²). A power density level of the second lower power density area 101c in the first end 101e1 and a power density level of the second lower power density area 102c in the second end 101e2 may be in a range from 0.01 W/mm² to 0.30 W/mm² (e.g., about 0.16 W/mm²).

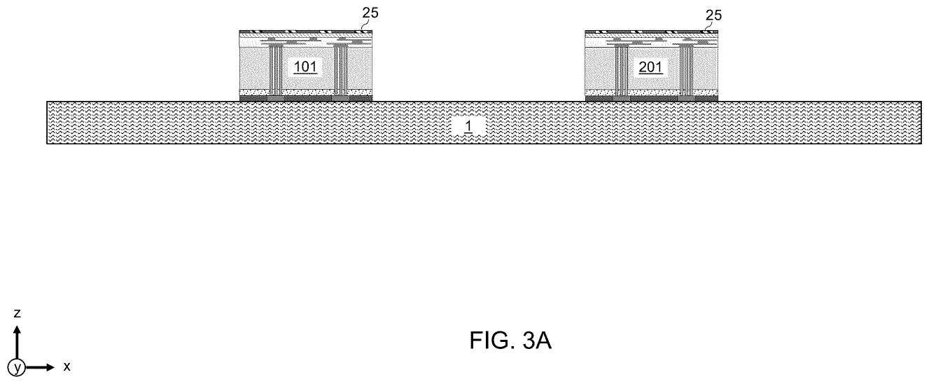

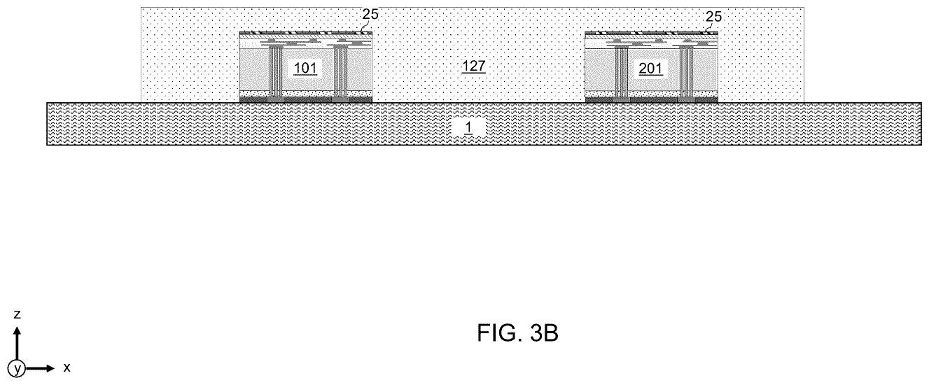

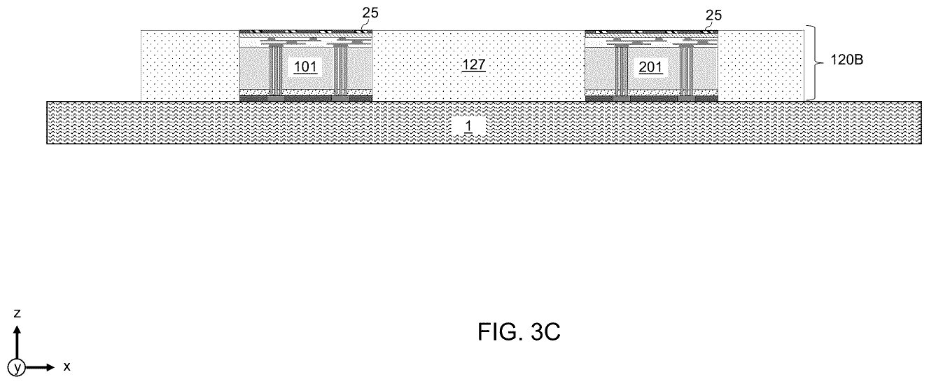

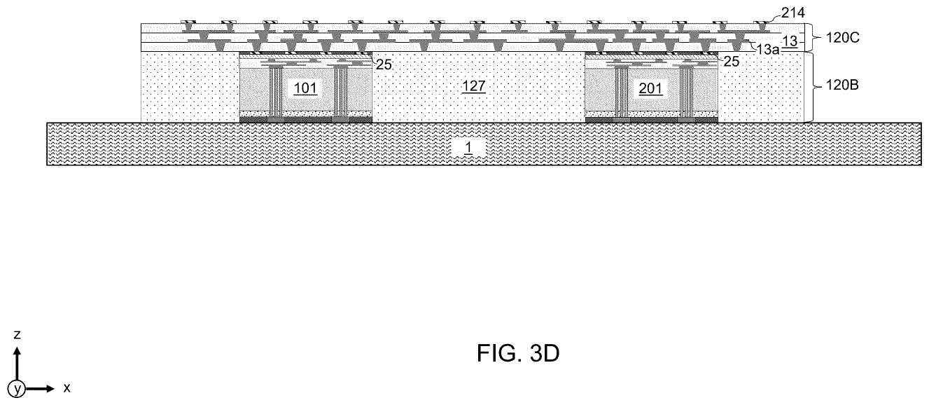

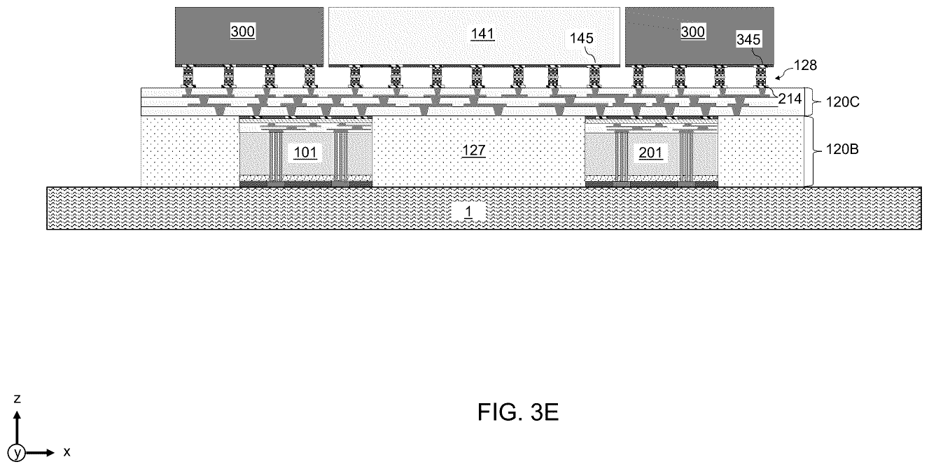

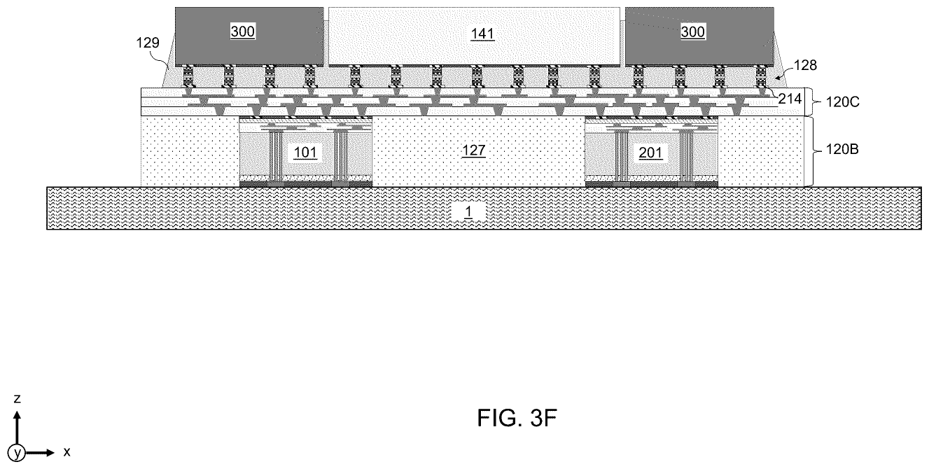

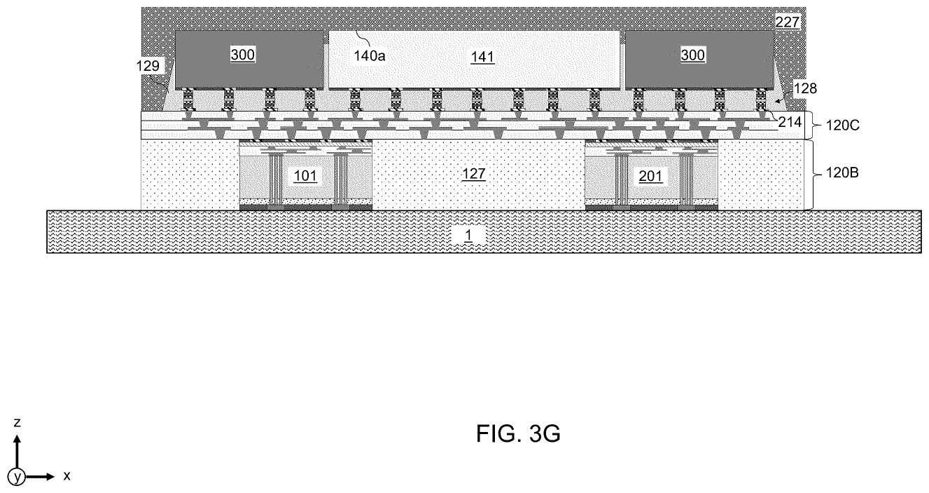

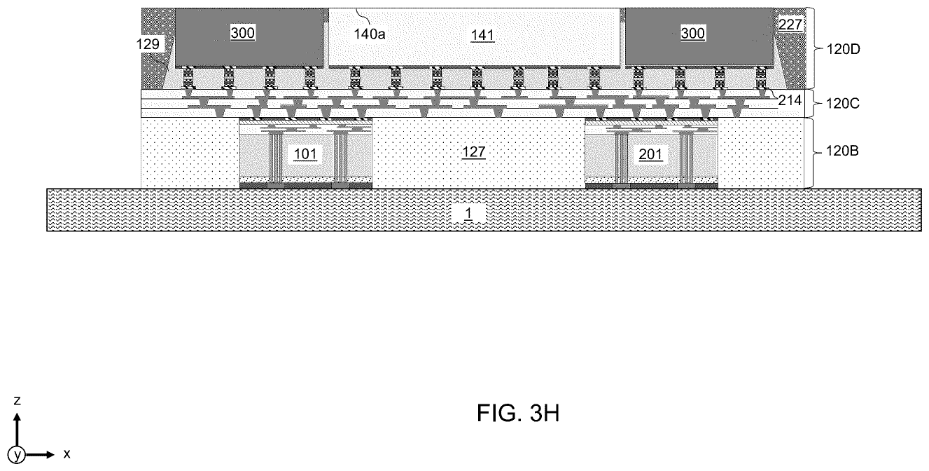

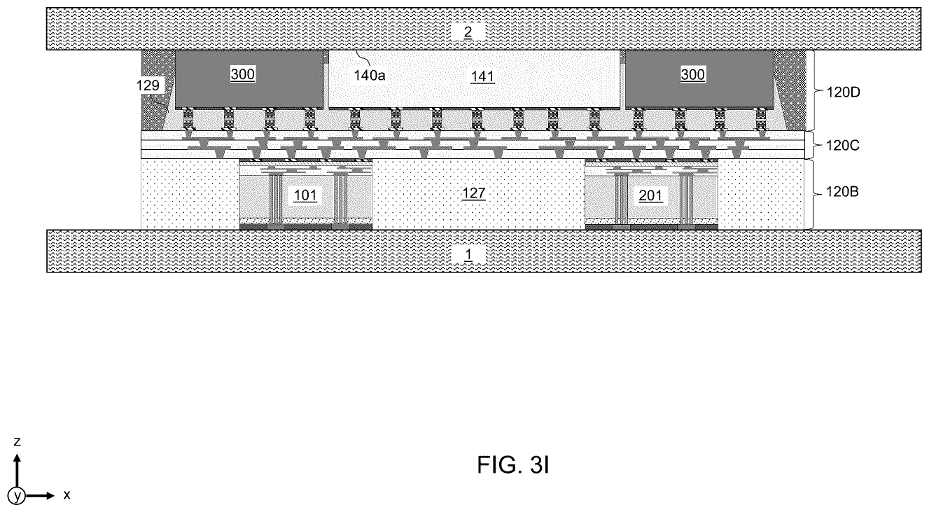

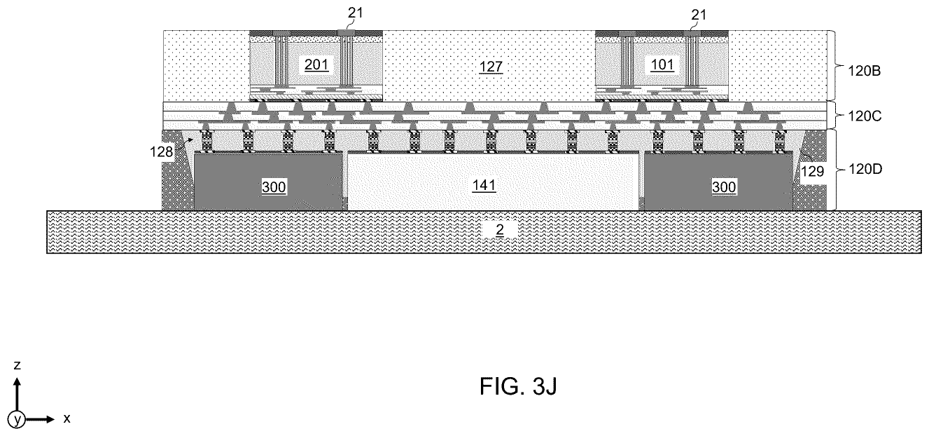

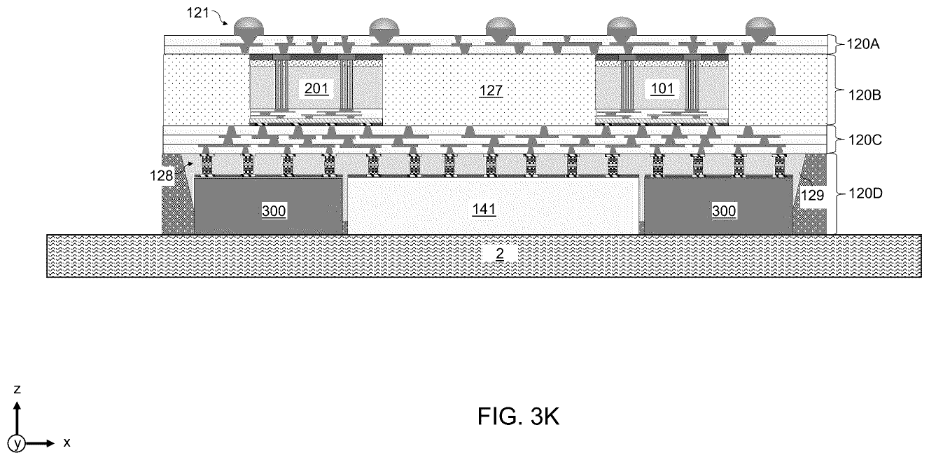

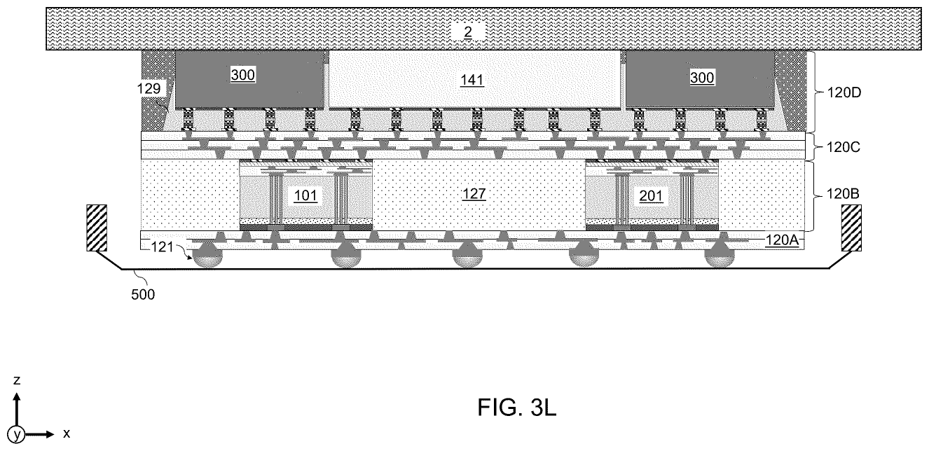

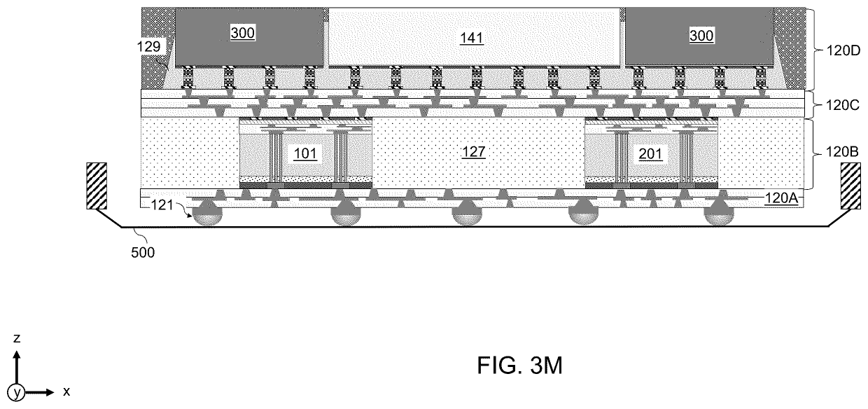

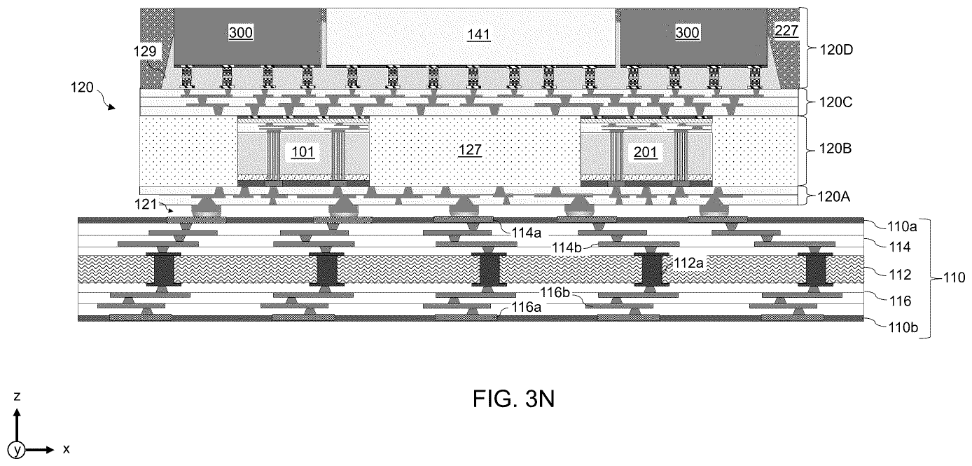

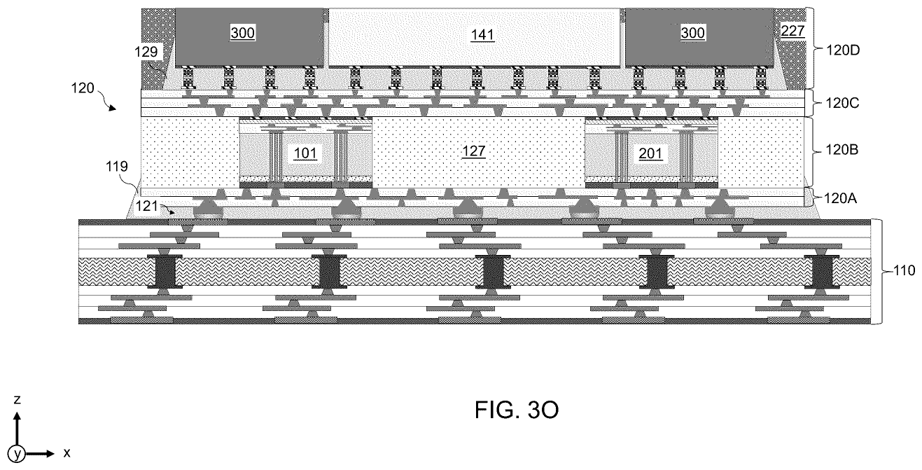

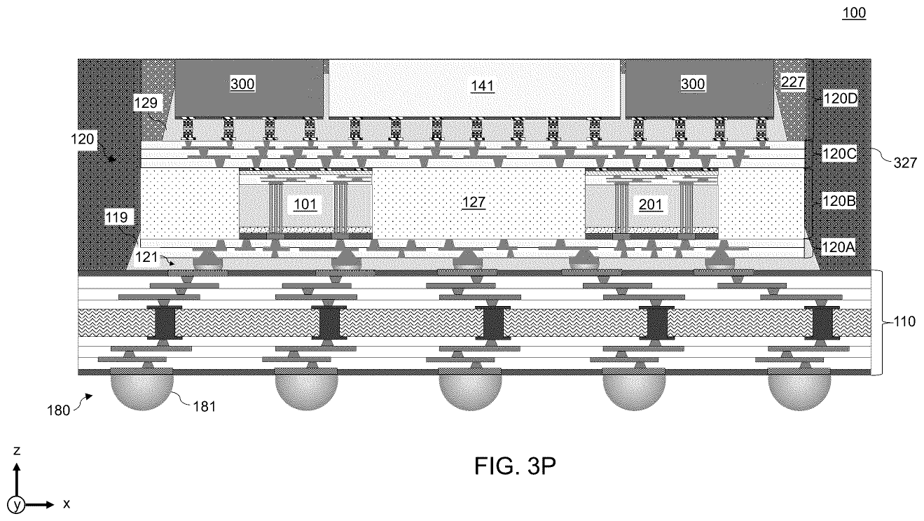

FIGS. 3A-3P illustrate various intermediate structures in a method of forming the package structure 100 according to one or more embodiments. FIG. 3A is a vertical cross-sectional view of an intermediate structure including the embedded active dies 101, 201 on a first carrier substrate 1 according to an embodiment of the present invention.

The first carrier substrate 1 may include a circular wafer or a rectangular wafer. The lateral dimensions (such as the diameter of a circular wafer or a side of a rectangular wafer) of the first carrier substrate 1 may be in a range from 100 mm to 500 mm, such as from 200 mm to 400 mm, although lesser and greater lateral dimensions may also be used. The first carrier substrate 1 may include a semiconductor substrate, an insulating substrate, or a conductive substrate. The first carrier substrate 1 may be transparent or opaque. A thickness of the first carrier substrate 1 may be sufficient to provide mechanical support to an array of interposers to be formed thereupon. For example, the thickness of the first carrier substrate 1 may be in a range from 60 microns to 1 mm, although lesser and greater thicknesses may also be used. In at least one embodiment, the carrier substrate 1 may include sapphire or glass and have a thickness of about 1000 μm.

An adhesive layer (e.g., die attach film (DAF); not shown) may be applied to the top surface of the first carrier substrate 1. The adhesive layer may include a light-to-heat conversion (LTHC) layer. The LTHC layer is a solvent-based coating applied using a spin coating method. The LTHC layer may form a layer that converts ultraviolet light to heat such that the LTHC layer loses adhesion. Alternatively, the adhesive layer may include a thermally decomposing adhesive material. For example, the adhesive layer may include an acrylic pressure-sensitive adhesive that decomposes at an elevated temperature. The debonding temperature of the thermally decomposing adhesive material may be in a range from 150° C. to 400° C. Other suitable thermally decomposing adhesive materials that decompose at other temperatures are within the contemplated scope of disclosure.

In at least one embodiment, the embedded active die 101 and embedded active die 201 may be placed on the first carrier substrate 1, for example, using an electromechanical pick-and-place (PNP) machine. As illustrated in FIG. 3A, a height of the upper contact pads 25 in the embedded active die 101 may be substantially the same as a height of the upper contact pads 25 in the embedded active die 201. The embedded active die 101 and embedded active die 201 may adhere to the first carrier substrate 1 by the adhesive layer (e.g., DAF; not shown).

FIG. 3B is a vertical cross-sectional view of an intermediate structure including the lower molding material layer 127 according to one or more embodiments. After the embedded active die 101 and embedded active die 201 are placed on the first carrier substrate 1, the lower molding material layer 127 (e.g., encapsulant layer) may be formed by a specialized molding process (e.g., A3+ molding process). The molding process may include, for example, preparing the molding compound (e.g., e.g., by mixing resin, hardener, fillers, and additives) and injecting (or depositing by spray coating, spin coating or other suitable method) the molding compound into a mold cavity around the embedded active die 101 and embedded active die 201. The molding compound may include an epoxy polymer material (e.g., an epoxy molding compound (EMC)). In at least one embodiment, the molding compound may be formed on the first carrier substrate 1 and fill in the gap between the embedded active die 101 and the embedded active die 201. The molding compound may encapsulate (e.g., in the x-direction, y-direction and z-direction) the embedded active die 101 and the embedded active die 201. The molding process may further include curing the mold compound to achieve desired mechanical and thermal properties, and post-mold processing such as trimming, testing, etc.

As illustrated in FIG. 3B, the lower molding material layer 127 may be formed to have a thickness greater than a height of the embedded active die 101 and a height of the embedded active die 201. In particular, the lower molding material layer 127 may be formed to have a thickness greater than a height of the upper contact pads 25 of the embedded active die 101 and the embedded active die 201. In at least one embodiment, the lower molding material layer 127 may be formed to have a thickness in a range from about 170 μm to 210 μm (e.g., about 190 μm).

FIG. 3C is a vertical cross-sectional view of an intermediate structure after polishing (e.g., planarizing) the lower molding material layer 127 according to one or more embodiments. After the lower molding material layer 127 has cured, a planarization process may then be used to make an upper surface of the lower molding material layer 127 substantially coplanar with an upper surface of the embedded active die 101 and an upper surface of the embedded active die 201. In particular, the planarization process may be performed on the upper surface of the lower molding material layer 127 to expose an upper surface of the upper contact pads 25 of the embedded active die 101 and embedded active die 201. In at least one embodiment, the planarization process may be performed until a thickness of the lower molded portion 120B is in a range from 110 μm to 150 μm (e.g., about 129 μm). The planarization process may include, for example, a mechanical grinding process and/or a CMP process. This may complete the formation of the lower molded portion 120B of the package module 120.

FIG. 3D is a vertical cross-sectional view of an intermediate structure including the upper RDL structure 120C according to one or more embodiments. The upper RDL structure 120C may be formed by alternately forming the plurality of dielectric layers 13 and plurality of redistribution layers 13a on the lower molded portion 120B. Each dielectric layer 13 may each be formed, for example, by depositing (e.g., by chemical vapor deposition (CVD), physical vapor deposition (PVD) or other suitable deposition technique) a layer of dielectric polymer material such as polyimide (PI), benzocyclobutene (BCB), or polybenzobisoxazole (PBO). Other suitable materials are within the contemplated scope of disclosure. The thickness of the layer of dielectric polymer material may be in a range from 4 microns to 60 microns, although lesser and greater thicknesses may also be used. The dielectric layer 13 may then be patterned by a photolithographic process to form via holes in the dielectric layer 13. The photolithographic process may include forming a patterned photoresist mask (not shown) on the layer of dielectric material, and etching (e.g., wet etching, dry etching, etc.) the exposed upper surface of the dielectric material through openings in the photoresist mask. The photoresist mask may be subsequently removed by ashing, dissolving the photoresist mask or by consuming the photoresist mask during the etch process.

A redistribution layer 13a (e.g., metal traces and metal vias) may be formed on the dielectric layer 13. The redistribution layer 13a may be formed, for example, by depositing (e.g., by CVD, PVD or other suitable deposition technique) one or more layers of metal material such as copper, aluminum, nickel, titanium, a combination thereof or other suitable metals, on the dielectric layer 13 and in the vias holes formed by patterning the dielectric layer 13. The redistribution layer 13a may then be patterned by a photolithographic process. The photolithographic process may include forming a patterned photoresist mask (not shown) on the layer of metal material, and etching (e.g., wet etching, dry etching, etc.) the exposed upper surface of the metal material through openings in the photoresist mask. The photoresist mask may be subsequently removed by ashing, dissolving the photoresist mask or by consuming the photoresist mask during the etch process.

As further illustrated in FIG. 3D, the bonding pads 214 may be formed on the uppermost dielectric layer 13. The bonding pads 214 may include a metallic material that may be bonded to a solder material. The bonding pads 214 may be formed by depositing (e.g., by CVD, PVD or other suitable deposition technique) one or more metal layers including a metal, metal alloys, and/or other metal-containing compounds (e.g., Cu, Al, Mo, Co, Ru, W, TiN, TaN, WN, etc.). The metal layer may then be patterned by a photolithographic process to form the bonding pads 214. The photolithographic process may include forming a patterned photoresist mask (not shown) on the metallic material, and etching (e.g., wet etching, dry etching, etc.) the exposed upper surface of the metallic material through openings in the photoresist mask. The photoresist mask may be subsequently removed by ashing, dissolving the photoresist mask or by consuming the photoresist mask during the etch process.

FIG. 3E is a vertical cross-sectional view of an intermediate structure including the first semiconductor die 141 and dummy dies 300 on the upper RDL structure 120C according to one or more embodiments. The second semiconductor dies 142 may be mounted on the upper RDL structure 120C concurrently with the first semiconductor die 141 in the same process.

The microbumps 128 may be formed to bond the semiconductor dies 140 to the upper RDL structure 120C. Each of the semiconductor dies 140 and dummy dies 300 may be bonded to the upper RDL structure 120C by one or more of the microbumps 128. In at least one embodiment, the microbumps 128 may include a two-dimensional array of microbumps 128. Each of the semiconductor dies 140 and dummy dies 300 may be attached to the bonding pads 214 by C2 bonding, (e.g., solder bonding).

The lower portion of the microbumps 128 (e.g., copper post and additional metal layers) may be formed on the bonding pads 214. The upper portion of the microbumps 128 (e.g., copper post and additional metal layers) may be formed on the die bonding pads 145 of the semiconductor dies 140 and on the die bonding pads 345 of the dummy dies 300. A solder layer may be formed, for example, on the lower portion of the microbumps 128.

The semiconductor dies 140 and dummy dies 300 (including the upper microbump portions) may then be positioned over the upper RDL structure 120C using an electromechanical PNP machine. The upper portion of the microbumps 128 on the semiconductor dies 140 and dummy dies 300 may be substantially aligned with the lower portion of the microbumps 128 on the upper RDL structure 120C. A C2 bonding process that reflows the solder layer may then be performed to create a solder joint between the upper portion of the microbumps 128 and lower portion of the microbumps 128.

FIG. 3F is a vertical cross-sectional view of an intermediate structure including the package module underfill layer 129 according to one or more embodiments. The package module underfill layer 129 may be applied by depositing and/or injecting an epoxy-based polymeric material onto the upper RDL structure 120C. The epoxy-based polymeric material may be applied on the upper RDL structure 120C so as to be formed under the semiconductor dies 140 and around the microbumps 128. In at least one embodiment, the epoxy-based polymeric material may fill substantially all of the gaps between the semiconductor dies 140 and the upper RDL structure 120C. The package module underfill layer 129 may then be cured, for example, in a box oven for about 90 minutes at about 150° C. to provide the package module underfill layer 129 with a sufficient stiffness and mechanical strength.

FIG. 3G is a vertical cross-sectional view of an intermediate structure including the upper molding material layer 227 according to one or more embodiments. The upper molding material layer 227 may be formed by dispensing a liquid molding material (e.g., EMC, epoxy molding material, A7 molding compound, etc.) onto the intermediate structure of FIG. 3F by a suitable dispensing tool. The upper molding material layer 227 may be dispensed onto the intermediate structure to have a height greater than the height of the upper surface 140a of the semiconductor dies 140. The semiconductor dies 140 may have a thickness, for example, in a range of about 400 μm to 1000 μm (e.g., about 692 μm).

In at least one embodiment, a dispensing of the molding material may be automated. In particular, various aspects of the dispensing process may be computer-controlled by a control system (e.g., electronic control system; central processing unit (CPU)). In at least one embodiment, a beginning of the dispensing of the molding material, a flow rate of the dispensing of the molding material, and a stopping of the dispensing of the molding material may be controlled by the control system. The control system may be programmed, for example, to dispense a predetermined amount of the molding material based on various input parameters. The input parameters may include, for example, a volume of the space around the upper RDL structure 120C, sizes of the semiconductor dies 140, etc.

In at least one embodiment, the molding material of the upper molding material layer 227 may include a capillary material (e.g., capillary underfill type material). The molding material may have a low viscosity. In particular, the viscosity may be less than about 5,000 cP at 10 rpm. In at least one embodiment, the molding material may include a low-viscosity suspension of thermally conductive material (e.g., metal, metal oxide) in prepolymer. The low viscosity may help to facilitate transport of the molding material around the semiconductor dies 140. The low viscosity may also help to avoid the formation of voids in the upper molding material layer 227. In at least one embodiment, the upper molding material layer 227 may be substantially free of voids.

FIG. 3H is a vertical cross-sectional view of an intermediate structure after polishing (e.g., planarizing) the upper molding material layer 227 according to one or more embodiments. After the upper molding material layer 227 has been adequately cured, the upper molding material layer 227 may be planarized so as to make the upper surface of the upper molding material layer 227 to be substantially coplanar with the semiconductor die upper surface 140a. The upper molding material layer 227 may be planarized, for example, by grinding, chemical mechanical polishing (CMP) or other suitable planarization technique. This may complete formation of the upper molded portion 120D of the package module 120.

FIG. 3I is a vertical cross-sectional view of an intermediate structure including a second carrier substrate 2 on the upper molded portion 120D according to one or more embodiments. The second carrier substrate 2 may have a structure substantially the same as the structure of the first carrier substrate 1 (e.g., having a thickness of about 550 μm). The second carrier substrate 2 may include an adhesive layer (e.g., DAF; not shown) which may help the second carrier substrate 2 to the upper molded portion 120D. The adhesive layer may be substantially similar to the adhesive layer used on the first carrier substrate 1.

FIG. 3J is a vertical cross-sectional view of an intermediate structure after detaching the first carrier substrate 1 according to one or more embodiments. As illustrated in FIG. 3J, after the second carrier substrate 2 is attached to the upper molded portion 120D, the intermediate structure of FIG. 3I may be inverted and the first carrier substrate 1 may be detached from the lower molded portion 120B. The first carrier substrate 1 may be detached from the lower molded portion 120B, for example, by deactivating the adhesive layer (e.g., DAF; not shown) adhering the first carrier substrate 1 to the lower molded portion 120B. The adhesive layer may be deactivated, for example, by a thermal anneal at an elevated temperature (e.g., for a thermally-deactivated adhesive material, or by exposing the adhesive layer to ultraviolet light (e.g., for an ultraviolet-deactivated adhesive material).

After the first carrier substrate 1 is detached from the lower molded portion 120B, a backside of the lower molded portion 120B including the lower molding material layer 127 may be planarized (e.g., by grinding, CMP, etc.). This planarizing step may help prepare a surface of the lower contact pads 21 of the embedded active die 101 and embedded active die 201.

FIG. 3K is a vertical cross-sectional view of an intermediate structure including the lower RDL structure 120A according to one or more embodiments. After planarizing the backside of the lower molded portion 120B, the lower RDL structure 120A may be formed on the backside of the lower molded portion 120B. The lower RDL structure 120A may be formed in a manner substantially similar to the manner of forming the upper RDL structure 120C (e.g., see FIG. 3D and associated text).

After the lower RDL structure 120A is formed, the C4 bumps 121 may be formed on the lower RDL structure 120A. The C4 bumps 121 may include, for example, a metal pillar (e.g., copper pillar) formed, for example, by an electroplating process. A solder bump (e.g., solder layer) may then be formed on the metal pillar. The solder bump may be formed on the metal pillar, for example, by one or more processes including ball mounting, electroplating, solder printing, solder immersion and solder injection.

FIG. 3L is a vertical cross-sectional view of an intermediate structure on a frame mount 500 according to one or more embodiments. After the C4 bumps 121 are formed on the lower RDL structure 120A, the intermediate structure may be inverted and placed on a frame mount 500. In particular, the C4 bumps 121 may contact an upper surface of the frame mount 500. The frame mount 500 may provide physical support to the intermediate structure and ensure that the intermediate structure is securely held in place during the fabrication process.

FIG. 3M is a vertical cross-sectional view of an intermediate structure after detaching the second carrier substrate 2 according to one or more embodiments. The second carrier substrate 2 may be detached (e.g., debonded) from the upper molded portion 120D in a manner substantially similar to the manner in which the first carrier substrate 1 was detached from the lower molded portion 120B. In particular, the second carrier substrate 2 may be detached by deactivating the adhesive layer (e.g., DAF; not shown) adhering the second carrier substrate 2 to the upper molded portion 120D. The adhesive layer may be deactivated, for example, by a thermal anneal at an elevated temperature (e.g., for a thermally-deactivated adhesive material, or by exposing the adhesive layer to ultraviolet light (e.g., for an ultraviolet-deactivated adhesive material).

After the second carrier substrate 2 is detached, the intermediate structure may be inverted and remounted on the frame mount 500. In particular, the intermediate structure may be mounted on the frame mount 500 such that the upper molded portion 120D contacts an upper surface of the frame mount 500. The C4 bumps 121 may then be cleaned to remove any adhesive material from the adhesive layer (e.g., DAF).

After the C4 bumps 121 are cleaned, a singulation process (e.g., dicing, sawing, etc.) may be performed. The singulation process may separate the package module 120 from surrounding wafer material and complete the formation of the package module 120.

FIG. 3N is a vertical cross-sectional view of an intermediate structure including the package module 120 on the package substrate 110 according to one or more embodiments. After the singulation process is performed, the package module 120 may be mounted on the package substrate 110. In at least one embodiment, an electromechanical PNP machine may be used to position the package module 120 over the package substrate 110. The electromechanical PNP machine may then lower the package module 120 onto the package substrate 110 so that the C4 bumps 121 contact the package substrate upper bonding pads 114a. A reflow process may then be performed to cause a reflow of the solder in the C4 bumps 121. The package module 120 may thereby be electrically coupled to the package substrate 110.

FIG. 3O is a vertical cross-sectional view of an intermediate structure including the package underfill layer 119 according to one or more embodiments. The package underfill layer 119 may be applied by depositing and/or injecting an epoxy-based polymeric material onto the package substrate 110. The epoxy-based polymeric material may be applied on the package substrate 110 and spread (e.g., by capillary action) under the package module 120 and around the C4 bumps 121. In at least one embodiment, the epoxy-based polymeric material may fill substantially all of the gaps between the package module 120 and the package substrate 110. The epoxy-based polymeric material may then be cured, for example, in a box oven for about 90 minutes at about 150° C. to provide the package underfill layer 119 with a sufficient stiffness and mechanical strength.

FIG. 3P is a vertical cross-sectional view of an intermediate structure including the outer molding material layer 327 according to one or more embodiments. After the package underfill layer 119 has cured, the outer molding material layer 327 may be formed around an outside of the package module 120. The outer molding material layer 327 may be formed in a manner similar to the manner of forming the upper molding material layer 227 (e.g., see FIG. 3G and associated text).

In particular, the outer molding material layer 327 may be formed by dispensing a liquid molding material (e.g., EMC, epoxy molding material, A7 molding compound, etc.) onto the intermediate structure of FIG. 3O by a suitable dispensing tool. In at least one embodiment, the outer molding material layer 327 may be dispensed onto the intermediate structure to have a height greater than a height of the package module 120 (e.g., greater than the height of the upper surface 140a of the semiconductor dies 140 and the upper surface of the upper molding material layer 227). A planarization process may then be used to make an upper surface of the outer molding material layer 327 substantially coplanar with the upper surface of the package module 120 (e.g., the upper surface 140a of the semiconductor dies 140 and upper surface of the upper molding material layer 227).

After the outer molding material layer 327 has been planarized, the intermediate structure may be inverted and the solder balls 181 of the BGA may be formed on the board-side surface of the package substrate 110. The solder balls 181 may be formed, for example, by one or more processes including ball mounting, electroplating, solder printing, solder immersion and solder injection. The forming of the solder balls 181 may complete the formation of the package structure 100.

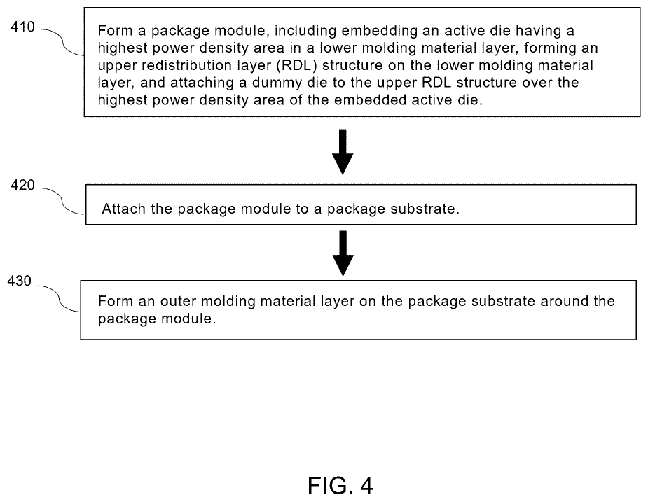

FIG. 4 is a flow chart illustrating a method of making the package structure 100 according to one or more embodiments. Step 410 includes forming a package module, including embedding an active die having a highest power density area in a lower molding material layer, forming an upper redistribution layer (RDL) structure on the lower molding material layer, and attaching a dummy die to the upper RDL structure over the highest power density area of the embedded active die. Step 420 includes attaching the package module to a package substrate. Step 430 includes forming an outer molding material layer on the package substrate around the package module.

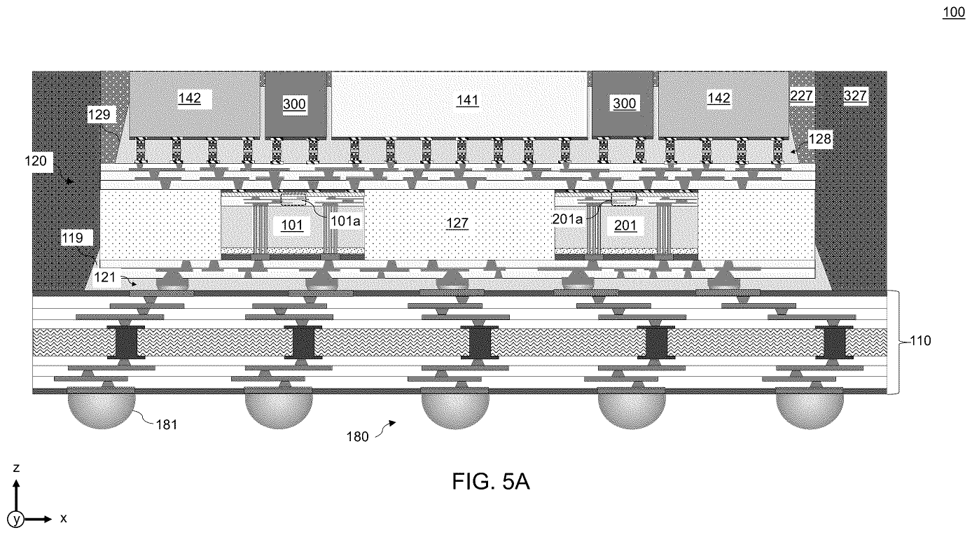

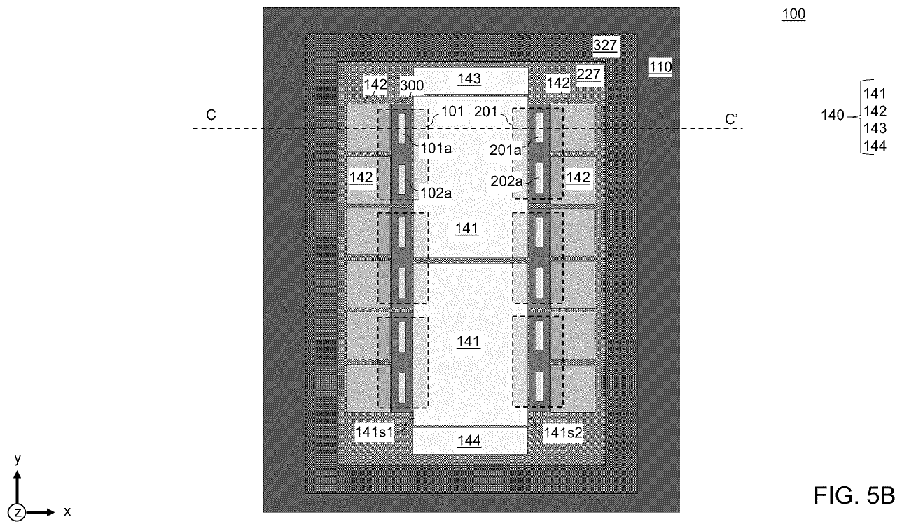

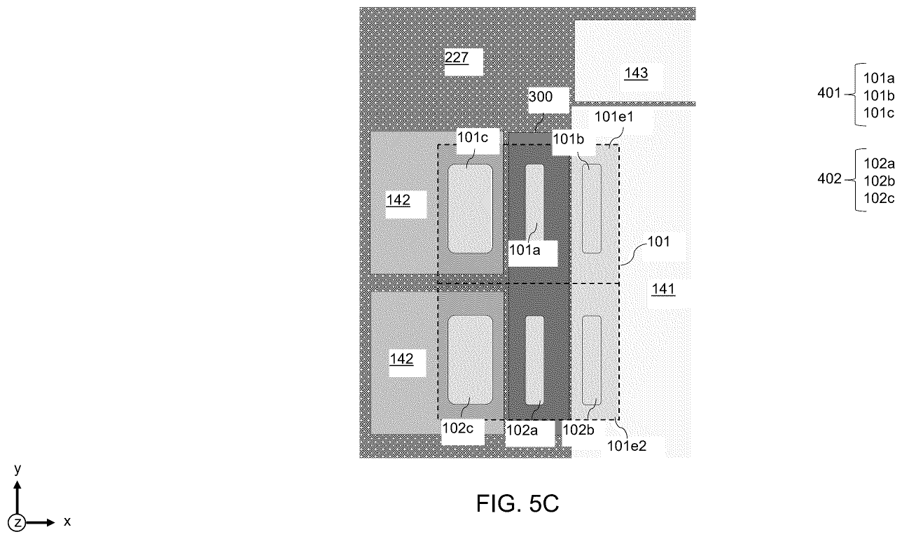

FIGS. 5A-5C are views of the package structure 100 having a first alternative configuration according to one or more embodiments. FIG. 5A is a vertical cross-sectional view of a package structure 100 having the first alternative configuration according to one or more embodiments. FIG. 5B is a plan view (e.g., top-down view) of the package structure 100 having the first alternative configuration according to one or more embodiments. The vertical cross-sectional view in FIG. 5A is along the line C-C′ in FIG. 5B. FIG. 5C is a detailed plan view (e.g., top-down view) of a portion of the package structure 100 having the first alternative configuration according to one or more embodiments.

As illustrated in FIG. 5A, the first alternative configuration of the package structure 100 may be substantially similar to the configuration in FIGS. 1A-1E. However, in the first alternative configuration, the dummy dies 300 and semiconductor dies 140 may have a different arrangement than in the configuration of FIGS. 1A-1E. In addition, the embedded active dies 101 may have a different configuration than the configuration in FIGS. 1A-1E.

In particular, the dummy dies 300 in the first alternative configuration may be located between the first semiconductor die 141 and the second semiconductor dies 142 in the first direction (x-direction). A dummy die 300 may be located over the highest power density area 101a in the embedded active die 101. The highest power density area 101a may have a width in the x-direction less than a width of the dummy die 300 in the x-direction. A dummy die 300 may also be located over the highest power density area 201a in the embedded active die 201. The highest power density area 201a may have a width in the x-direction less than a width of the dummy die 300 in the x-direction.

Referring to FIG. 5B, since the structure on the first side 141s1 of the first semiconductor dies 141 may be substantially the same as the structure on the second side 141s2 of the first semiconductor dies 141, the description of the package structure 100 having the first alternative configuration in FIG. 5B may at be limited to the structure on the first side 141s1 of the first semiconductor dies 141. As illustrated in FIG. 5B, the embedded active die 101 may extend lengthwise in the second direction (y-direction). The highest power density areas 101a and 102a in the embedded active die 101 may also extend lengthwise in the second direction. The highest power density areas 101a and 102a may also be substantially aligned in the second direction. The highest power density areas 101a and 102a may also be located in a center of the embedded active die 101 in the first direction.

The highest power density area 101a of the embedded active die 101 may be located between a second semiconductor die 142 and the first semiconductor die 141 in the first direction. The highest power density area 101a may also be substantially aligned with the second semiconductor die 142 in the first direction. The highest power density area 101a may have a length in the second direction (y-direction) less than a length of the second semiconductor die 142 in the second direction.

The highest power density area 102a of the embedded active die 101 may also be located between a second semiconductor die 142 and the first semiconductor die 141 in the first direction. The highest power density area 102a may be substantially aligned with the second semiconductor die 142 in the first direction. The highest power density area 102a may also have a length in the second direction (y-direction) less than a length of the second semiconductor die 142 in the second direction.

Referring to FIG. 5C, as with the configuration in FIGS. 1A-1E, in the first alternative configuration, the embedded active die 101 may be designed so that the power density in the first end 101e1 of the embedded active die 101 is concentrated primarily in the highest power density area 101a. The embedded active die 101 may also be designed so that the power density in the second end 101e2 is concentrated primarily in the highest power density area 102a.

As illustrated in FIG. 5C, the high power density areas 401 in the first end 101e1 of the embedded active die 101 may be substantially aligned in the first direction. The highest power density area 101a may be located under the dummy die 300 between the first lower power density area 101b and the second lower power density area 101c. The first lower power density area 101b may be located under the first semiconductor die 141 and the second lower power density area 101c may be located under a second semiconductor die 142.

The high power density areas 402 in the second end 101e2 of the embedded active die 101 may also be substantially aligned in the first direction. The high power density areas 402 may also be substantially aligned with the high power density areas 401 in the second direction. The highest power density area 102a may be located under the dummy die 300 between the first lower power density area 102b and the second lower power density area 102c. The first lower power density area 102b may be located under the first semiconductor die 141 and the second lower power density area 102c may be located under a second semiconductor die 142.

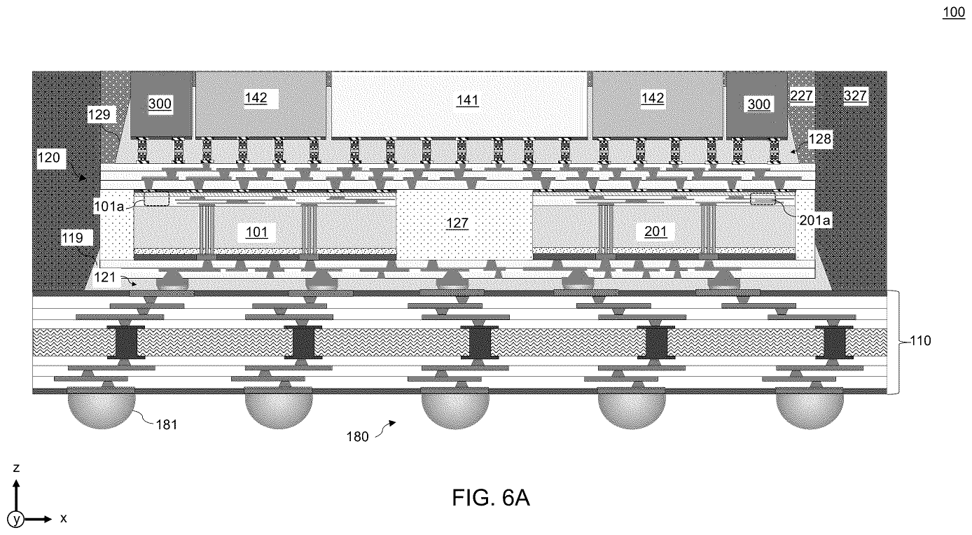

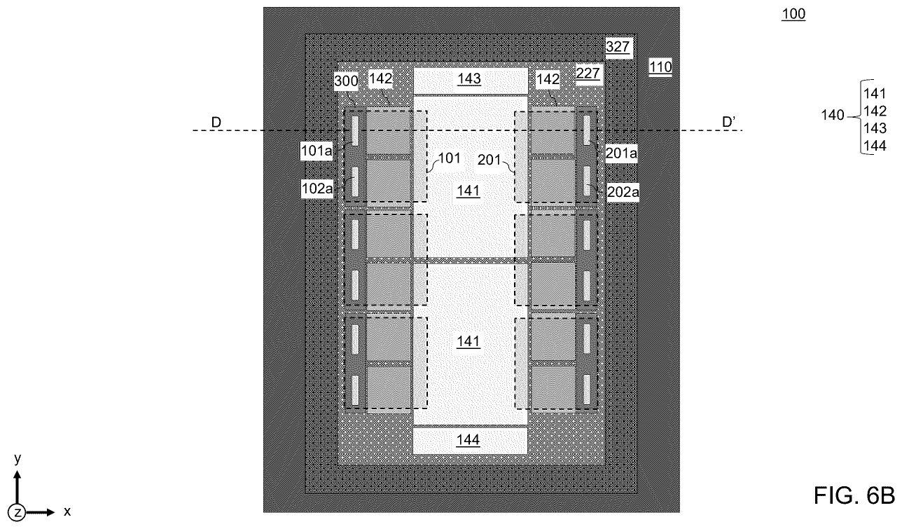

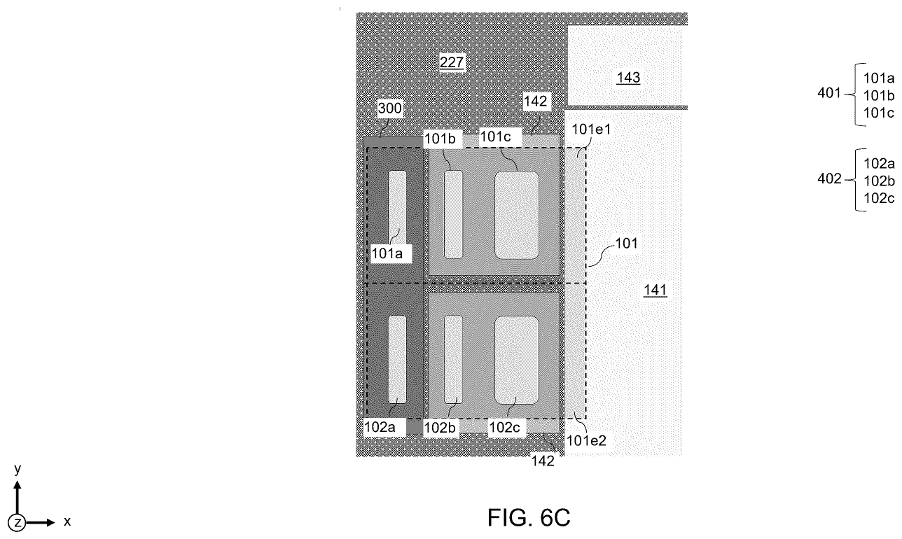

FIGS. 6A-6C are views of the package structure 100 having a second alternative configuration according to one or more embodiments. FIG. 6A is a vertical cross-sectional view of a package structure 100 having the second alternative configuration according to one or more embodiments. FIG. 6B is a plan view (e.g., top-down view) of the package structure 100 having the second alternative configuration according to one or more embodiments. The vertical cross-sectional view in FIG. 6A is along the line D-D′ in FIG. 6B. FIG. 6C is a detailed plan view (e.g., top-down view) of a portion of the package structure 100 having the second alternative configuration according to one or more embodiments.

As illustrated in FIG. 6A, the second alternative configuration of the package structure 100 may be substantially similar to the configuration in FIGS. 1A-1E and the first alternative configuration in FIGS. 5A-5C. However, in the second alternative configuration, the dummy dies 300 and semiconductor dies 140 may have a different arrangement than in the configuration of FIGS. 1A-1E and the first alternative configuration of FIGS. 5A-5C. In addition, the embedded active dies 101 may have a different configuration than the configuration in FIGS. 1A-1E and the first alternative configuration of FIGS. 5A-5C.

In particular, the second semiconductor dies 142 in the second alternative configuration may be located between the dummy dies 300 and the first semiconductor die 141 in the first direction (x-direction). A dummy die 300 may be located over the highest power density area 101a in the embedded active die 101. The highest power density area 101a may have a width in the x-direction less than a width of the dummy die 300 in the x-direction. A dummy die 300 may also be located over the highest power density area 201a in the embedded active die 201. The highest power density area 201a may have a width in the x-direction less than a width of the dummy die 300 in the x-direction.

Referring to FIG. 6B, since the structure on the first side 141s1 of the first semiconductor dies 141 may be substantially the same as the structure on the second side 141s2 of the first semiconductor dies 141, the description of the package structure 100 having the second alternative configuration in FIG. 6B may at be limited to the structure on the first side 141s1 of the first semiconductor dies 141. As illustrated in FIG. 6B, the embedded active die 101 may extend lengthwise in the second direction (y-direction). In at least one embodiment, the embedded active die 101 may have a substantially square shape. The embedded active die 101 may have an outer sidewall substantially aligned with an outer sidewall of the dummy die 300. The embedded active die 101 may extend in the first direction across an entire length of the dummy die 300 in the first direction and across the entire length of the second semiconductor dies 142 in the first direction. At least a portion of the embedded active die 101 may be located under the first semiconductor die 141.

The highest power density areas 101a and 102a in the embedded active die 101 may extend lengthwise in the second direction. The highest power density areas 101a and 102a may also be substantially aligned in the second direction. The highest power density areas 101a and 102a may also be located in a center of the embedded active die 101 in the first direction.

A second semiconductor die 142 may be located between the highest power density area 101a of the embedded active die 101 and the first semiconductor die 141 in the first direction. The highest power density area 101a may be substantially aligned with the second semiconductor die 142 in the first direction. The highest power density area 101a may have a length in the second direction (y-direction) less than a length of the second semiconductor die 142 in the second direction.

Another second semiconductor die 142 may be located between the highest power density area 102a of the embedded active die 101 and the first semiconductor die 141 in the first direction. The highest power density area 102a may be substantially aligned with the second semiconductor die 142 in the first direction. The highest power density area 102a may have a length in the second direction (y-direction) less than a length of the second semiconductor die 142 in the second direction.

Referring to FIG. 6C, as with the configuration in FIGS. 1A-1E and the first alternative configuration in FIGS. 5A-5C, in the second alternative configuration, the embedded active die 101 may be designed so that the power density in the first end 101e1 of the embedded active die 101 is concentrated primarily in the highest power density area 101a. The embedded active die 101 may also be designed so that the power density in the second end 101e2 is concentrated primarily in the highest power density area 102a.

As illustrated in FIG. 6C, the high power density areas 401 in the first end 101e1 of the embedded active die 101 may be substantially aligned in the first direction. The highest power density area 101a may be located under the dummy die 300 and the first lower power density area 101b and the second lower power density area 101c may be located between the highest power density area 101a and the first semiconductor die 141. The first lower power density area 101b may be located adjacent the highest power density area 101a under the second semiconductor die 142. The second lower power density area 101c may be located adjacent the first lower power density area 101b under the second semiconductor die 142.

The high power density areas 402 in the second end 101e2 of the embedded active die 101 may be substantially aligned in the first direction. The highest power density area 102a may be located under the dummy die 300 and the first lower power density area 102b and the second lower power density area 102c may be located between the highest power density area 102a and the first semiconductor die 141. The first lower power density area 102b may be located adjacent the highest power density area 102a under the second semiconductor die 142. The second lower power density area 102c may be located adjacent the first lower power density area 102b under the second semiconductor die 142.

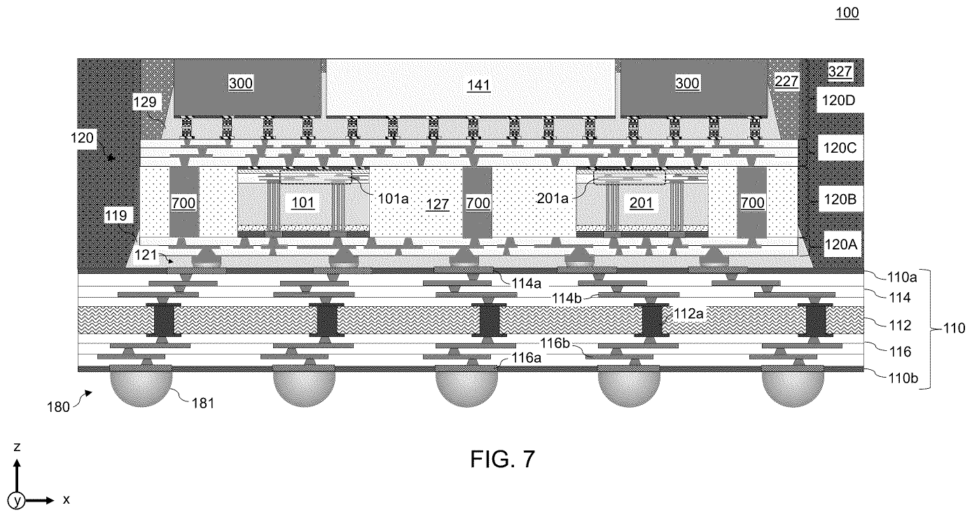

FIG. 7 is a vertical cross-sectional view of a package structure 100 having the third alternative configuration according to one or more embodiments. As illustrated in FIG. 7, the third alternative configuration of the package structure 100 may be substantially similar to the configuration in FIGS. 1A-1E. However, in the third alternative configuration, one or more thermal vias 700 may be formed in the lower molding material layer 127. The thermal vias 700 may help to dissipate heat from the embedded active dies 101 and 201 in the lower molding material layer 127. The thermal vias 700 may, therefore, help to reduce the risk of increasing the temperature of the second semiconductor dies 142 (e.g., HBM devices) caused by heat from high power density areas in the embedded active dies 101, 201.

The thermal vias 700 may be formed, for example, of substantially the same material as the TSVs 22a in the embedded active dies 101, 201. The thermal vias 700 may extend across an entire thickness of the lower molding material layer 127. The thermal vias 700 may extend from an upper surface of the lower RDL structure 120A to a lower surface of the upper RDL structure 120C. The thermal vias 700 may be electrically isolated from the lower RDL structure 120A and/or the upper RDL structure 120C. The thermal vias 700 may alternatively or additionally be electrically coupled to the lower RDL structure 120A and/or the upper RDL structure 120C. As illustrated in FIG. 7, in at least one embodiment, the embedded active dies 101, 201 may be located adjacent one or more of the thermal vias 700 in the lower molding material layer 127, and the dummy dies 300 may be located over the thermal vias 700 and the first area 101a, 201a of the embedded active dies 101, 201.

The thermal vias 700 may have a width (e.g., diameter) in the first direction (x-direction) in a range from 1% to 10% of a width of the embedded active dies 101, 201. The thermal vias 700 may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

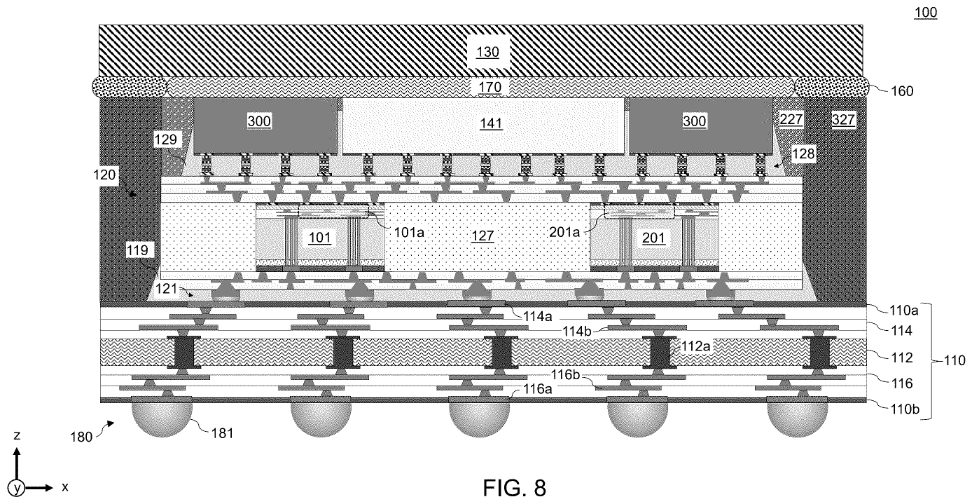

FIG. 8 is a vertical cross-sectional view of a package structure 100 having the fourth alternative configuration according to one or more embodiments. As illustrated in FIG. 8, the fourth alternative configuration of the package structure 100 may be substantially similar to the configuration in FIGS. 1A-1E. However, the package structure 100 having the fourth alternative configuration may include a thermal interface material (TIM) layer 170 on the package module 120, and a package lid 130 on the TIM layer 170 and attached to the outer molding material layer 327 by an adhesive layer 160.

In the fourth alternative configuration, the dummy dies 300 may be located between the highest power density areas 101a in the embedded active die 101 and the package lid 130. The dummy dies 300 may also be located between the highest power density areas 201a in the embedded active die 201 and the package lid 130. With this configuration, a thermal conduit may be provided from the embedded active dies 101, 201 through the dummy dies 300 and the TIM layer 170 into the package lid 130. The TIM layer 170 and package lid 130 may, therefore, help to reduce the risk of increasing the temperature of the second semiconductor dies 142 (e.g., HBM devices) caused by heat from high power density areas in the embedded active dies 101, 201.

The TIM layer 170 may include one or more layers. In at least one embodiment, a center of the TIM layer 170 may be substantially aligned with a center of the package module 120. The TIM layer 170 may have a low bulk thermal impedance and high thermal conductivity. The TIM layer 170 may cover an entire area of the upper surface of the package module 120. In at least one embodiment, the TIM layer 170 may have a thickness (e.g., a greatest thickness in the z-direction) in a range from 100 μm to 300 μm. The TIM layer 170 may be attached to the upper surface of the package module 120 by a thermally conductive adhesive (not shown).

In at least one embodiment, the TIM layer 170 may include one or more metals. The TIM layer 170 may include, for example, a low-melting-temperature (LMT) metal TIM or liquid metal TIM. The TIM layer 170 may include one or more metals such as indium, tin, gallium, silver, etc. The TIM layer 170 may include, for example, a gallium base, indium base, silver base, solder base, etc. The solder base may include tin and one or more other elements such as copper, silver, bismuth, indium, zinc, antimony, etc.

The TIM layer 170 may alternatively or additionally include a thermal grease, a thermal paste, thermal film, thermal adhesive, thermal gap filler, thermal pad (e.g., silicone), thermal tape or a gel-type TIM (e.g., a cross-linked polymer film). In at least one embodiment, the TIM layer 170 may include graphite, carbon nanotubes (CNTs), phase-change material (PCM), etc. The PCM may include, for example, a polymer based PCM. In at least one embodiment, the PCM may change its phase from solid to high-viscosity semi liquid around 60° C. Other materials in the TIM layer 170 are within the contemplated scope of this disclosure.

The TIM layer 170 may be formed on the package module 120 to dissipate of heat generated during operation of the package structure 100 (e.g., operation of the semiconductor dies 140). The TIM layer 170 may have a low bulk thermal impedance and high thermal conductivity. The bond-line-thickness (BLT) (e.g., a distance between the package lid 130 and the package module 120) may be less than about 100 μm, although greater or lesser distances may be used. The BLT may also be substantially uniform over the entire area of the upper surface of the package module 120.

An adhesive layer 160 may be formed on the upper surface of the outer molding material layer 327. The adhesive layer 160 may serve to contain a spread of the TIM layer 170 as the TIM layer 170 is compressed between the package lid 130 and the package module 120. A thickness of the adhesive layer 160 may be in a range from 50 μm to 200 μm. In at least one embodiment, the thickness of the adhesive layer 160 may be substantially the same as a thickness of the TIM layer 170. The adhesive layer 160 may include, for example, a silicone adhesive (e.g., containing aluminum oxide, zinc oxide, resin, etc.) or an epoxy adhesive. Other suitable adhesives may be used.

The package lid 130 may be located on the TIM layer 170 and attached to the outer molding material layer 327. The package lid 130 may be attached to the outer molding material layer 327 by the adhesive layer 160. The package lid 130 may cover an entirety of the package module 120 and an entirety of the outer molding material layer 327. The package lid 130 may contact (e.g., directly contact) at least a portion of the TIM layer 170. In one or more embodiments, the package lid 130 may directly contact an entire upper surface of the TIM layer 170. The TIM layer 170 and the adhesive layer 160 may be compressed between the package lid 130 and the package module 120. The package lid 130 may include, for example, a ceramic material or metal material such as Cu, Ag, Al, stainless steel, CuAg alloy and CuNi alloy. Other materials may be used for the package lid 130.

Referring again to FIGS. 1A-8, a package structure 100 including a package substrate 110, a package module 120 on the package substrate 110 including a first encapsulant layer 127, and an active die 101, 201 in the first encapsulant layer 127, wherein the active die 101, 201 includes a first area 101a, 102a, 201a, 202a with a first power density and a second area 101b, 101c, 102b, 102c with a second power density, and the first power density may be greater than the second power density. The package module 120 may further include a dummy die 300 over the first area 101a, 102a, 201a, 202a of the active die 101, 201, and the package structure 100 may further include a second encapsulant layer 327 on the package substrate 110 around the package module 120.

In at least one embodiment, the first power density may be the highest power density in the active die 101, 201. The first power density may be greater than 0.1 W/mm 2. The first power density may be greater than 0.9W/mm 2 . The first area 101a, 102a, 201a, 202a may include a first area 101a, 102a, 201a, 202a in a first end 101e1 of the active die 101, 201 and a first area 101a, 102a, 201a, 202a in a second end 101e2 of the active die 101, 201 opposite the first end 101e1, and the dummy die 300 may be located over the first area 101a, 102a, 201a, 202a in the first end 101e1 of the active die 101, 201 and the first area 101a, 102a, 201a, 202a in the second end 101e2 of the active die 101, 201. The package module 120 further may include a plurality of semiconductor dies 140 over the active die 101, 201, the plurality of semiconductor dies 140 may include a first semiconductor die 141 and a plurality of second semiconductor dies 142, and the dummy die 300 may be adjacent the plurality of second semiconductor dies 142. The plurality of second semiconductor dies 142 may include a stacked structure of memory dies. The plurality of second semiconductor dies 142 may include a first column of second semiconductor dies 142 on a first side of the first semiconductor die 141 in a first direction, and the first semiconductor die 141 may extend lengthwise in a second direction perpendicular to the first direction. The plurality of second semiconductor dies 142 includes a second semiconductor die 142 adjacent a first side of the dummy die 300 in the second direction and a second semiconductor die 142 adjacent a second side of the dummy die 300 opposite the first side of the dummy die 300 in the second direction. The second semiconductor die 142 adjacent the first side of the dummy die 300 may be over the first end 101e1 of the active die 101, 201, and the second semiconductor die 142 adjacent the second side of the dummy die 300 may be over the second end 101e2 of the active die 101, 201. The first semiconductor die 141 may be adjacent to the dummy die 300 and at least one of the plurality of second semiconductor dies 142 in the first direction, the dummy die 300 may extend lengthwise in the first direction and the active die 101, 201 may extend lengthwise in the second direction. The dummy die 300 may be between the first semiconductor die 141 and the plurality of second semiconductor dies 142 in the first direction, the dummy die 300 may extend lengthwise in the second direction and the active die 101, 201 may extend lengthwise in the second direction. The plurality of second semiconductor dies 142 may be between the first semiconductor die 141 and the dummy die 300 in the first direction, the dummy die 300 may extend lengthwise in the second direction and the active die 101, 201 may extend across an entire width of the plurality of second semiconductor dies 142 in the first direction. The package structure 100 may further include a thermal interface material (TIM) layer 170 on the package module 120, and a package lid 130 on the TIM layer 170 and attached to the second encapsulant layer 327 by an adhesive layer 160, wherein the dummy die 300 may be located between the first area 101a, 102a, 201a, 202a of the active die 101, 201 and the package lid 130. The package module 120 further may include a first semiconductor die 141 and a plurality of second semiconductor dies 142, the active die 101, 201 may include a plurality of second area 101b, 101c, 102b, 102cs having a power density less than the first area 101a, 102a, 201a, 202a, and the plurality of second semiconductor dies 142 may be over the second area 101b, 101c, 102b, 102cs.

Referring again to FIGS. 1A-8, a method of making a package structure 100 may include forming a package module 120 including encapsulating an active die 101, 201 in a first encapsulant layer 127, wherein the active die 101, 201 includes a first area 101a, 102a, 201a, 202a with a first power density and a second area 101b, 101c, 102b, 102c with a second power density, and the first power density may be greater than the second power density, forming an upper redistribution layer (RDL) structure 120C on the first encapsulant layer 127, and attaching a dummy die 300 to the upper RDL structure 120C over the first area 101a, 102a, 201a, 202a of the active die 101, 201. The method may also include attaching the package module 120 to a package substrate 110, and forming a second encapsulant layer 327 on the package substrate 110 around the package module 120.

In at least one embodiment, the forming of the package module 120 further may include attaching a first semiconductor die 141 and a plurality of second semiconductor dies 142 on the upper RDL structure 120C, and the attaching of the dummy die 300 to the upper RDL structure 120C may include attaching the dummy die 300 to the upper RDL structure 120C such that the dummy die 300 may be between the plurality of second semiconductor dies 142. The forming of the package module 120 further may include attaching a first semiconductor die 141 and a plurality of second semiconductor dies 142 on the upper RDL structure 120C, and the attaching of the dummy die 300 to the upper RDL structure 120C may include attaching the dummy die 300 to the upper RDL structure 120C such that the dummy die 300 may be between the first semiconductor die 141 and the plurality of second semiconductor dies 142. The forming of the package module 120 further may include attaching a first semiconductor die 141 and a plurality of second semiconductor dies 142 on the upper RDL structure 120C, and the attaching of the dummy die 300 to the upper RDL structure 120C may include attaching the dummy die 300 to the upper RDL structure 120C such that the plurality of second semiconductor dies 142 may be between the first semiconductor die 141 and the dummy die 300.

Referring again to FIGS. 1A-8, a package structure 100 may include a package substrate 110, a package module 120 on the package substrate 110 including a first encapsulant layer 127, a thermal via 700 in the first encapsulant layer 127, and an active die 101, 201 adjacent the thermal via 700 in the first encapsulant layer 127, wherein the active die 101, 201 includes a first area 101a, 102a, 201a, 202a with a first power density and a second area 101b, 101c, 102b, 102c with a second power density, and the first power density may be greater than the second power density. The package module 120 may further include a dummy die 300 over the thermal via 700 and the first area 101a, 102a, 201a, 202a of the active die 101, 201, and the package structure 100 may further include a second encapsulant layer 327 on the package substrate 110 around the package module 120.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a package substrate;
a package module on the package substrate, comprising:
a first encapsulant layer;
an active die in the first encapsulant layer, wherein the active die includes a first area with a first power density and a second area with a second power density, and the first power density is greater than the second power density; and
a dummy die over the first area of the active die; and
a second encapsulant layer on the package substrate around the package module.

2. The package structure of claim 1, wherein the first power density is the highest power density in the active die.

3. The package structure of claim 1, wherein the first power density is greater than 0.1 W/mm².

4. The package structure of claim 1, wherein the first power density is greater than 0.9 W/mm².

5. The package structure of claim 1, wherein the first area comprises a first area in a first end of the active die and a first area in a second end of the active die opposite the first end, and the dummy die is located over the first area in the first end of the active die and the first area in the second end of the active die.

6. The package structure of claim 5, wherein the package module further comprises a plurality of semiconductor dies over the active die, the plurality of semiconductor dies comprises a first semiconductor die and a plurality of second semiconductor dies, and the dummy die is adjacent the plurality of second semiconductor dies.

7. The package structure of claim 6, wherein the plurality of second semiconductor dies comprises a stacked structure of memory dies.

8. The package structure of claim 6, wherein the plurality of second semiconductor dies comprises a first column of second semiconductor dies on a first side of the first semiconductor die in a first direction, and the first semiconductor die extends lengthwise in a second direction perpendicular to the first direction.

9. The package structure of claim 8, wherein the plurality of second semiconductor dies includes a second semiconductor die adjacent a first side of the dummy die in the second direction and a second semiconductor die adjacent a second side of the dummy die opposite the first side of the dummy die in the second direction.

10. The package structure of claim 9, wherein the second semiconductor die adjacent the first side of the dummy die is over the first end of the active die, and the second semiconductor die adjacent the second side of the dummy die is over the second end of the active die.

11. The package structure of claim 9, wherein the first semiconductor die is adjacent to the dummy die and at least one of the plurality of second semiconductor dies in the first direction, the dummy die extends lengthwise in the first direction and the active die extends lengthwise in the second direction.

12. The package structure of claim 8, wherein the dummy die is between the first semiconductor die and the plurality of second semiconductor dies in the first direction, the dummy die extends lengthwise in the second direction and the active die extends lengthwise in the second direction.

13. The package structure of claim 8, wherein the plurality of second semiconductor dies are between the first semiconductor die and the dummy die in the first direction, the dummy die extends lengthwise in the second direction and the active die extends across an entire width of the plurality of second semiconductor dies in the first direction.

14. The package structure of claim 1, further comprising:
a thermal interface material (TIM) layer on the package module; and
a package lid on the TIM layer and attached to the second encapsulant layer by an adhesive layer, wherein the dummy die is located between the first area of the active die and the package lid.

15. The package structure of claim 1, wherein the package module further comprises a first semiconductor die and a plurality of second semiconductor dies, the active die comprises a plurality of second areas having a power density less than the first area, and the plurality of second semiconductor dies are over the second areas.

16. A method of making a package structure, the method comprising:
forming a package module, comprising:
encapsulating an active die in a first encapsulant layer, wherein the active die includes a first area with a first power density and a second area with a second power density, and the first power density is greater than the second power density;
forming an upper redistribution layer (RDL) structure on the first encapsulant layer; and
attaching a dummy die to the upper RDL structure over the first area of the active die;
attaching the package module to a package substrate; and
forming a second encapsulant layer on the package substrate around the package module.

17. The method of claim 16, wherein the forming of the package module further comprises attaching a first semiconductor die and a plurality of second semiconductor dies on the upper RDL structure, and the attaching of the dummy die to the upper RDL structure comprises attaching the dummy die to the upper RDL structure such that the dummy die is between the plurality of second semiconductor dies.

18. The method of claim 16, wherein the forming of the package module further comprises attaching a first semiconductor die and a plurality of second semiconductor dies on the upper RDL structure, and the attaching of the dummy die to the upper RDL structure comprises attaching the dummy die to the upper RDL structure such that the dummy die is between the first semiconductor die and the plurality of second semiconductor dies.

19. The method of claim 16, wherein the forming of the package module further comprises attaching a first semiconductor die and a plurality of second semiconductor dies on the upper RDL structure, and the attaching of the dummy die to the upper RDL structure comprises attaching the dummy die to the upper RDL structure such that the plurality of second semiconductor dies is between the first semiconductor die and the dummy die.

20. A package structure, comprising:
a package substrate;
a package module on the package substrate, comprising:
a first encapsulant layer;
a thermal via in the first encapsulant layer;
an active die adjacent the thermal via in the first encapsulant layer,
wherein the active die includes a first area with a first power density and a second area with a second power density, and the first power density is greater than the second power density; and
a dummy die over the thermal via and the first area of the active die; and
a second encapsulant layer on the package substrate around the package module.
